(19) United States
(12) Patent Application Publication
(10) Pub. No.: US 2026/0181978 A1
(43) Pub. Date: Jun. 25, 2026

(54) TECHNOLOGIES FOR A HIGH-GRADIENT OF DOPANT CONCENTRATION IN GATE-ALL-AROUND TRANSISTORS

(71) Applicant: Intel Corporation, Santa Clara, CA (US)

(72) Inventors: Patrick M. Wallace, Hillsboro, OR (US); Robert Ehlert, Portland, OR (US); Sandrine Charue-Bakker, Portland, OR (US); Md Rezaul Karim, Beaverton, OR (US); Yulia Tolstova, Kirkland, WA (US); Ethan James Nagasing, Portland, OR (US); Anushka Bansal, Portland, OR (US); James Kally, Hillsboro, OR (US); Shishir Pandya, Hillsboro, OR (US); Alexander Badmaev, Portland, OR (US); Zhiyi Chen, Portland, OR (US); Glenn Glass, Portland, OR (US); Jonathan Ludwig, Portland, OR (US); Sanjay Rangan, Tigard, OR (US)

(73) Assignee: Intel Corporation, Santa Clara, CA (US)

(21) Appl. No.: 19/001,193

(22) Filed: Dec. 24, 2024

(51) Int. Cl. H10D 62/60; H01L 21/02; H10D 30/00; H10D 62/00; H10D 62/13

(52) U.S. Cl. CPC H10D 62/60; H10D 30/501; H10D 62/021; H10P 14/24; H10D 62/151; H10P 14/3411

(57) ABSTRACT

Technologies for a high gradient of dopant concentration in gate-all-around transistors are disclosed. In an illustrative embodiment, a source/drain region of a gate-all-around transistor may have a relatively high dopant concentration, such as a dopant concentration of over 10²⁰ cm⁻³, and an adjacent channel region may have a relatively low dopant concentration, such as a dopant concentration of less than 10¹⁸ cm⁻³. At an interface between the source/drain region and the channel region, the logarithmic slope of the dopant concentration may be high, such as two orders of magnitude in less than a nanometer. In order to maintain such a high dopant concentration, the source/drain region with a high dopant concentration is deposited using a low-temperature deposition technique after high-temperature processing steps are completed.

### BACKGROUND

Transistors are ubiquitous devices present in virtually all electronic devices. As the density of transistors continues to increase, new architectures such as fin field effect transistors (FETs) and gate-all-around (GAA) FETs are used to reduce the footprint of a transistor. A GAA FET may include several nanoribbons or nanowires vertically stacked on top of each other. The channel region may have a different dopant concentration than the source and drain regions, with a high dopant concentration in the source and drain regions and a lower dopant concentration in the channel region. In some cases, manufacturing steps can cause migration of the dopants, which can reduce device performance.

### BRIEF DESCRIPTION OF THE DRAWINGS

FIG. 1 is an isometric view of a gate-all-around field-effect transistor.

FIG. 2 is a cross-sectional side view of one embodiment of the transistor of FIG. 1.

FIG. 3 is a cross-sectional side view of one embodiment of the transistor of FIG. 1.

FIG. 4 is a cross-sectional side view of one embodiment of the transistor of FIG. 1.

FIG. 5 is a simplified flow diagram of at least one embodiment of a method for creating the transistor of FIG. 1.

FIG. 6 is a cross-sectional side view at one step of the flow diagram of FIG. 5.

FIG. 7 is a cross-sectional side view at one step of the flow diagram of FIG. 5.

FIG. 8 is a cross-sectional side view at one step of the flow diagram of FIG. 5.

FIG. 9 is a cross-sectional side view at one step of the flow diagram of FIG. 5.

FIG. 10 is a cross-sectional side view at one step of the flow diagram of FIG. 5.

FIG. 11 is a cross-sectional side view at one step of the flow diagram of FIG. 5.

FIG. 12 is a cross-sectional side view at one step of the flow diagram of FIG. 5.

FIG. 13 is a cross-sectional side view at one step of a flow diagram of at least one embodiment of a method for creating a gate-all-around transistor.

FIG. 14 is a simplified flow diagram of at least one embodiment of a method for creating a gate-all-around transistor.

FIG. 15 is a cross-sectional side view at one step of the flow diagram of FIG. 14.

FIG. 16 is a cross-sectional side view at one step of the flow diagram of FIG. 14.

FIG. 17 is a cross-sectional side view at one step of the flow diagram of FIG. 14.

FIG. 18 is a cross-sectional side view at one step of the flow diagram of FIG. 14.

FIG. 19 is a cross-sectional side view at one step of the flow diagram of FIG. 14.

FIG. 20 is a simplified flow diagram of at least one embodiment of a method for creating a gate-all-around transistor.

FIG. 21 is a cross-sectional side view at one step of the flow diagram of FIG. 20.

FIG. 22 is a cross-sectional side view at one step of the flow diagram of FIG. 20.

FIG. 23 is a simplified flow diagram of at least one embodiment of a method for creating a gate-all-around transistor.

FIG. 24 is a cross-sectional side view at one step of the flow diagram of FIG. 23.

FIG. 25 is a cross-sectional side view at one step of the flow diagram of FIG. 23.

FIG. 26 is a graph showing a dopant concentration as a function of position for one embodiment of a gate-all-around transistor.

FIG. 27 is a top view of a wafer and dies that may be included in a microelectronic assembly in accordance with any of the embodiments disclosed herein.

FIG. 28 is a cross-sectional side view of an integrated circuit device that may be included in any of the microelectronic assemblies disclosed herein.

FIGS. 29A-29D are perspective views of example planar, FinFET, gate-all-around, and stacked gate-all-around transistors.

FIG. 30 is a cross-sectional side view of an integrated circuit device assembly that may include a microelectronic assembly in accordance with any of the embodiments disclosed herein.

FIG. 31 is a block diagram of an example electrical device that may include a microelectronic assembly in accordance with any of the embodiments disclosed herein.

### DETAILED DESCRIPTION

In one embodiment disclosed herein, as described in more detail below, a source/drain region of a gate-all-around (GAA) field effect transistor (FET) has a relatively high dopant concentration, such as more than 10²¹ cm⁻³, and a channel region of the GAA FET has a relatively low dopant concentration, such as less than 10¹⁹ cm⁻³. The dopant concentration increases over a relatively short distance, such as an increase of two orders of magnitude in less than a nanometer. As used herein, an order of magnitude refers to a factor of ten, so an increase of two orders of magnitude in less than a nanometer corresponds to an increase by a factor of 100 in less than a nanometer, such as an increase from less than 10¹⁹ cm⁻³ to more than 10²¹ cm⁻³ in less than a nanometer.

High dopant concentration in the source/drain regions can reduce the resistivity of the semiconductor material. However, at high temperatures, such as those experienced during certain steps of manufacturing a wafer with GAA FETs, the dopants can diffuse into neighboring materials, such as the channel region of the transistor. Dopant diffusion into the channel region can reduce electron mobility via carrier scattering and can also form low resistivity leakage paths under the gate of the GAA FET.

In an illustrative embodiment and as described in more detail below, a high gradient concentration can be achieved by creating a trench for the source/drain regions and filling the trench with a sacrificial material. After processing steps that require high-temperatures are complete, the sacrificial material can be removed, and source/drain regions with high dopant concentrations can be deposited at low temperatures using techniques described below. Depositing the dopant concentrations at a low temperature and after high-temperature processing steps are complete allow for a high logarithmic slope of the dopant concentration, allowing for high dopant concentration in the source and drain region and low dopant concentration in the channel region.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc., means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

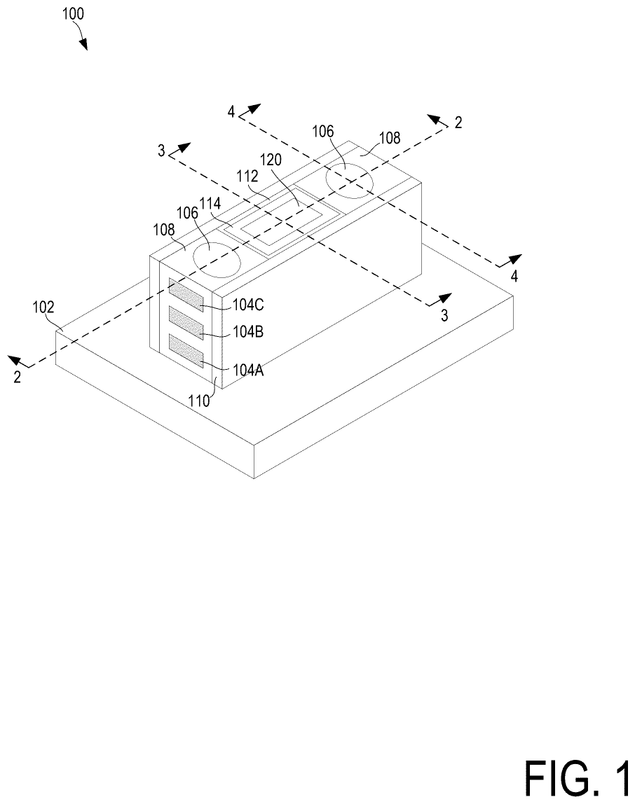

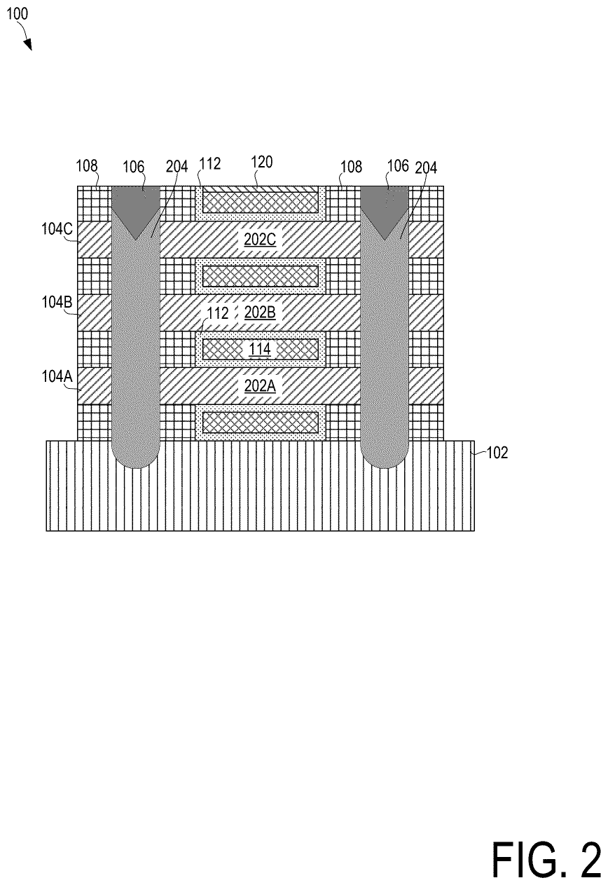

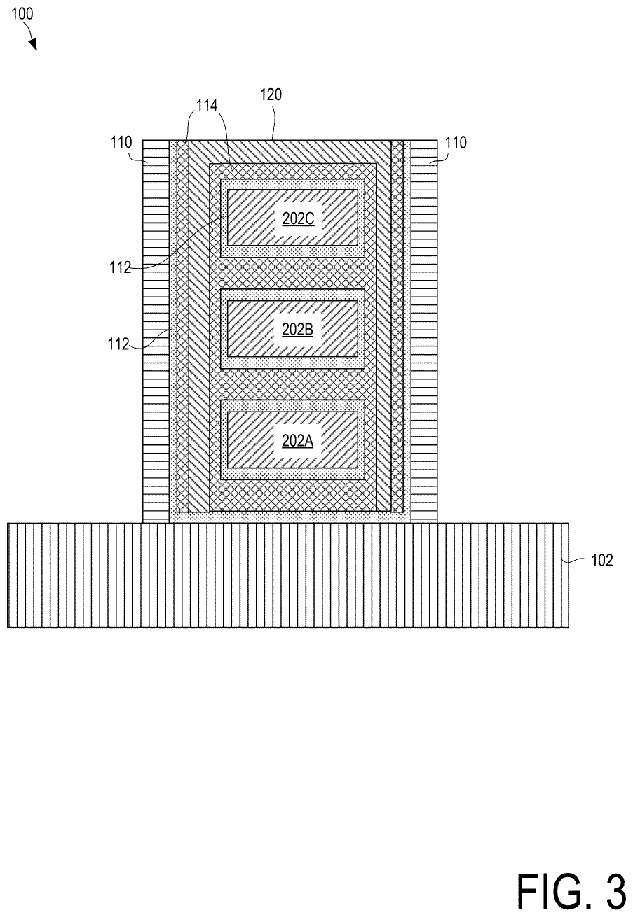

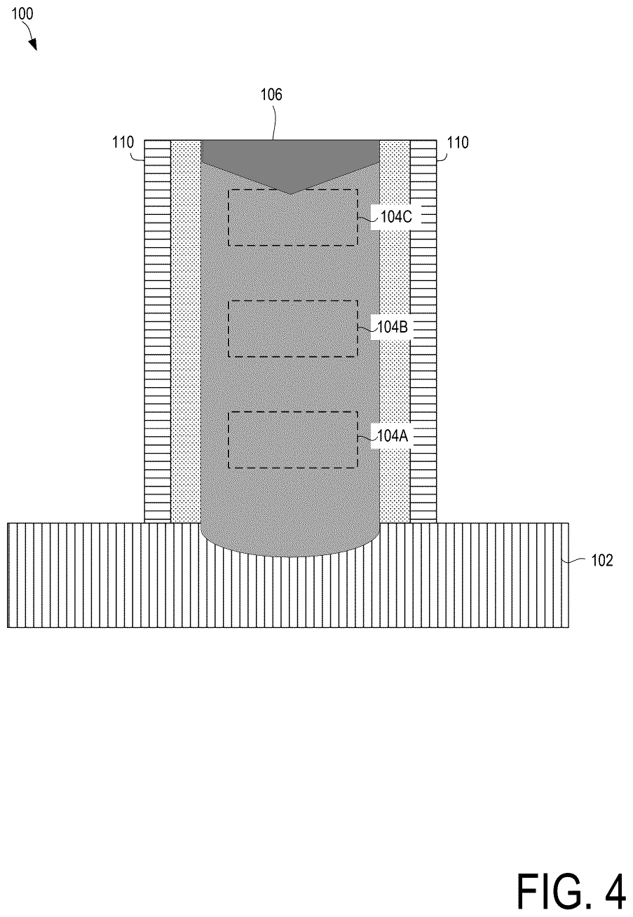

Referring now to FIGS. 1-4, in one embodiment, FIG. 1 shows a perspective view of a GAA FET 100, FIG. 2 shows a cross-sectional view of the GAA FET 100 taken from view 2 labeled in FIG. 1, FIG. 3 shows a cross-sectional view of the GAA FET 100 taken from view 3 labeled in FIG. 1, and FIG. 4 shows a cross-sectional view of the GAA FET 100 taken from view 4 labeled in FIG. 1. In some embodiments, the GAA FET 100 may also be referred to as a ribbon FET transistor, a nanoribbon transistor, a nanowire transistor, a nanosheet transistor, etc.

The GAA FET 100 is supported by a substrate 102. The GAA FET 100 has one or more semiconductor nanoribbons 104A, 104B, and 104C. The semiconductor nanoribbons 104A-C include channel regions 202A, 202B, and 202C (see FIGS. 2 and 3). Source/drain regions 204 are on either side of the channel regions 202A-C. Dielectric spacers 108 are in between the source/drain regions 204 and the region with the channel regions 202A-C, gate 114, and gate dielectric layer 112. A gate dielectric layer 112 surrounds the channel regions 202A-C inside the region bounded by the dielectric spacers 108 and the dielectric isolation layers 110. The gate 114 surrounds the gate dielectric layer 112 and the channel regions 202A-C. A conductive material 120 is on top of the gate 114. Dielectric isolation layers 110 surround the channel regions 202A-C and other structures of the GAA FET 100. A contact 106 is on top of each source/drain region 204.

As described in more detail below, the source/drain regions 204 are formed separately from the rest of the nanoribbons 104A-C and from the channel regions 202A-C. In an illustrative embodiment, the source/drain regions 204 have a relatively high dopant concentration, such as more than 10²¹ per cubic centimeter (cm⁻³), and the channel regions 202A-C and/or the rest of the nanoribbons 104A-C have a relatively low dopant concentration, such as less than 10¹⁹ cm⁻³. The dopant concentration increases over a relatively short distance, such as an increase of two orders of magnitude in less than a nanometer at an interface between the source/drain regions 204 and the channel regions 202A-C. The high dopant concentration in the source/drain regions 204 provides a low resistivity, and the low dopant concentration in the channel regions 202A-C maintains a high electron mobility due to less carrier scattering and also reduces formation of low resistivity leakage paths under the gate 114 of the GAA FET 100. In some cases, the interface between the source/drain regions 204 and a channel region 202A-C may be referred to as a separate region, where there is a gradient of dopant concentration. In other cases, the region where there is a gradient of dopant concentration may be considered part of the source/drain regions 204 and/or the channel regions 202A-C.

The substrate 102 supports the rest of the GAA FET 100. In the illustrative embodiment, the substrate 102 is silicon. In other embodiments, the substrate 102 may be, e.g., silicon oxide, gallium nitride, a perovskite, strontium titanium oxide, etc.

The GAA FET 100 may be a n-MOS transistor or a p-MOS transistor. The semiconductor nanoribbons 104A-C may be made from any suitable material or combination of materials, such as undoped or lightly doped semiconductor. In the illustrative embodiment, the channel regions 202A-C and the nanoribbons 104A-C are undoped or lightly doped silicon, such as silicon with a dopant concentration of less than, e.g., 10¹⁵-10¹⁹ cm⁻³. The channel regions 202A-C may refer to regions of the nanoribbons 104A-C that are surrounded by the gate dielectric layer 112 and gate 114 as well as to regions of the nanoribbons 104A-C that extend further, into regions dielectric isolation layers 110 separated by the dielectric spacers 108 and the dielectric isolation layers 110. In an illustrative embodiment, the channel region 202A-C refers to the region of the nanoribbons 104A-C between the source-drain regions 204. The illustrative source/drain regions 204 are silicon doped with, e.g., phosphorous or arsenic. More generally, the source/drain regions 204 and channel regions 202A-C or other part of the nanoribbons 104A-C may be made of any suitable combination of doped or undoped semiconductors, such a silicon, silicon-germanium, germanium, germanium-tin alloys, germanium-silicon-tin alloys, a III-V semiconductor, a perovskite, a compound semiconductor, etc. The source/drain regions 204 may have any suitable concentration of any suitable dopant, such as a dopant concentration of 10¹⁷-10²³ cm⁻³ of phosphorous, arsenic, boron, aluminum, indium, gallium, antimony, and/or the like.

The contact 106 on top of the source/drain regions 204 may be any suitable material, such as a metal silicide and/or a metal such as tungsten, molybdenum, niobium, ruthenium, and/or the like. The contact 106 may be connected to one or more redistribution or interconnect layers.

In the illustrative embodiment, the GAA FET 100 are symmetric, and there is no structural distinction between, e.g., the source of the GAA FET 100 and the drain of the GAA FET 100. As such, the source/drain region 204 may be the source region or the drain region. Accordingly, as used herein, a “source or drain region” may refer to a region that may act as the source of a transistor or to a region that may act as the drain of a transistor.

The nanoribbon 104A-C and channel regions 202A-C, B, 204D-E may have any suitable dimensions, such as a thickness or width of, e.g., 0.5-20 nanometers and a length of, e.g., 2-50 nanometers. The source/drain regions 204 may have any suitable dimensions, such as a width (into/out of the page) of 10-70 nanometers. The source/drain regions 204 may have any suitable length (across the page) of 5-50 nanometers. The source/drain regions 204 may have any suitable height, such as a height of 10-100 nanometers. The GAA FET 100 may include any suitable number of semiconductor nanoribbons 104A-C, such as 1-8.

In the illustrative embodiment, the dielectric spacers 108 are a low-k material such as, e.g., silicon oxide or silicon nitride. The dielectric isolation layers 110 may be made of any suitable material, such as silicon oxide or silicon nitride. The dielectric isolation layers 110 may have any suitable dimension, such as a length along the substrate 102 of, e.g., 2-50 nanometers, a height of, e.g., 5-50 nanometers, and a width of, e.g., 2-30 nanometers.

The gate dielectric layer 112 may be any suitable dielectric, such as a high-K dielectric. In the illustrative embodiment, the gate dielectric layer is hafnium oxide. The gate dielectric layer 112 may have any suitable thickness, such as a thickness of about 0.5-25 nanometers.

The illustrative gate 114 may include at least one p-type work function metal or n-type work function metal, depending on whether the transistor is to be a p-type metal oxide semiconductor (p-MOS) or an n-type metal oxide semiconductor (n-MOS) transistor. In some implementations, the gate 114 may include a stack of two or more metal layers, where one or more metal layers are work function metal layers and at least one metal layer is a fill metal layer. For a p-MOS transistor, metals that may be used for the gate 114 include, but are not limited to, ruthenium, palladium, platinum, cobalt, nickel, conductive metal oxides (e.g., ruthenium oxide), and any of the metals discussed below with reference to an n-MOS transistor (e.g., for work function tuning). For an n-MOS transistor, metals that may be used for the gate 114 include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a p-MOS transistor (e.g., for work function tuning). The conductive material 120 that is adjacent the gate 114 may be any suitable conductor. In the illustrative embodiment the conductive material 120 is tungsten.

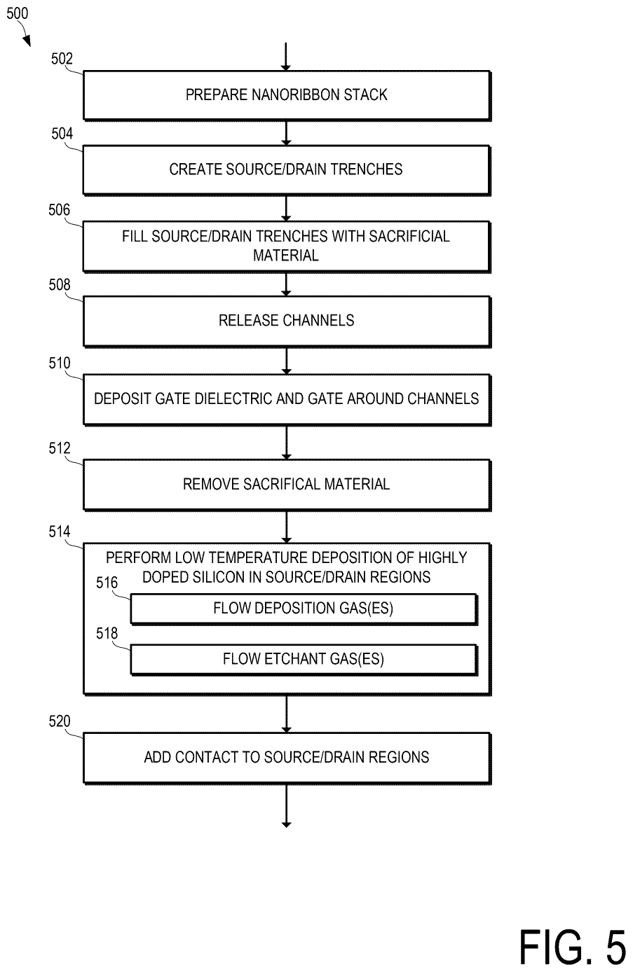

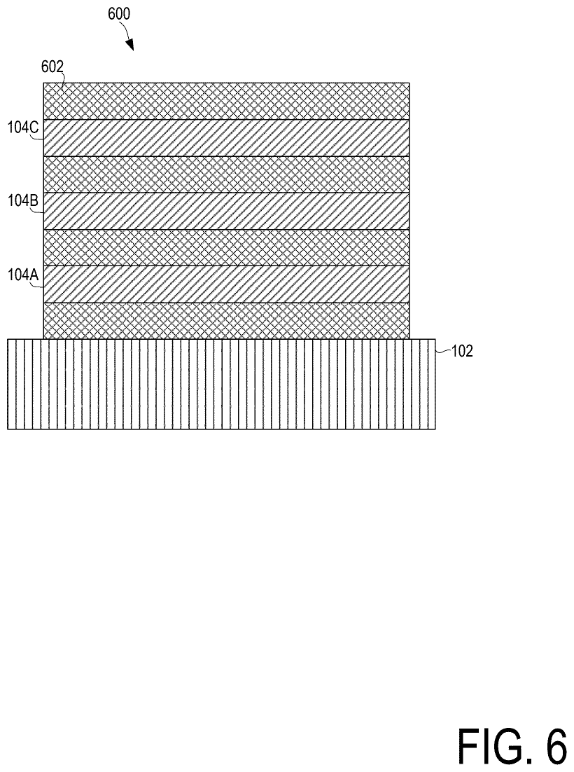

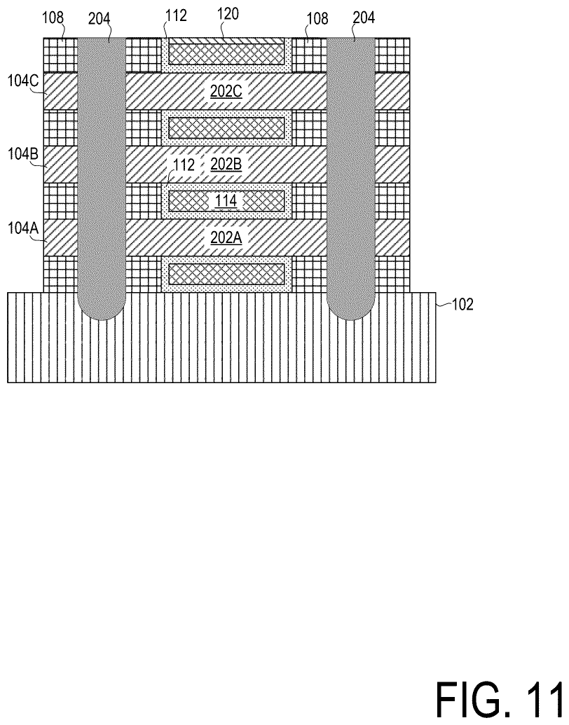

Referring now to FIG. 5, in one embodiment, a flowchart for a method 500 for creating a transistor is shown. The method 500 may be executed by a technician and/or by one or more automated machines. In some embodiments, one or more machines may be programmed to do some or all of the steps of the method 500. Such a machine may include, e.g., a memory, a processor, data storage, etc. The memory and/or data storage may store instructions that, when executed by the machine, causes the machine to perform some or all of the steps of the method 500. The method 500 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, plasma etching, reactive ion etching, ion-assisted chemical vapor etching, thermal treatments, etc. FIGS. 6-12 show various stages of the method 500 from the same perspective as FIG. 2.

The method 500 begins in block 502, in which a stack 600 of semiconductor nanoribbons 104A-C is prepared. In the illustrative embodiment, the stack 600 includes alternating layers of silicon-germanium 602 and silicon nanoribbons 104A-C, as shown in FIG. 6.

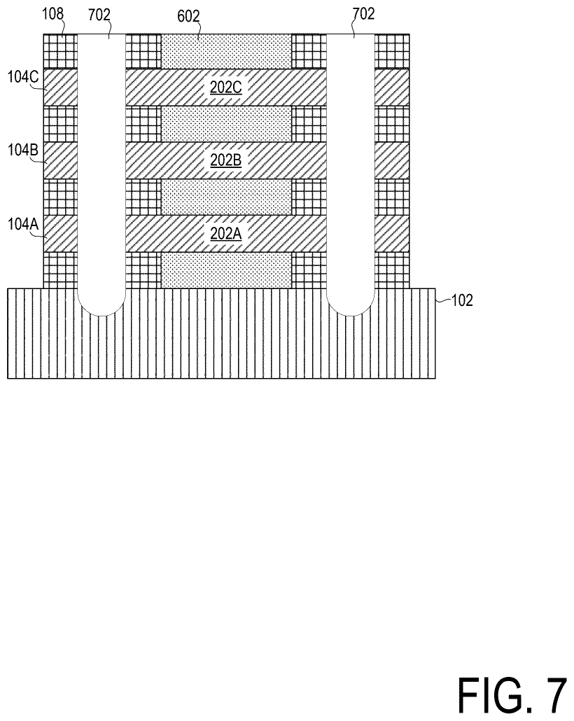

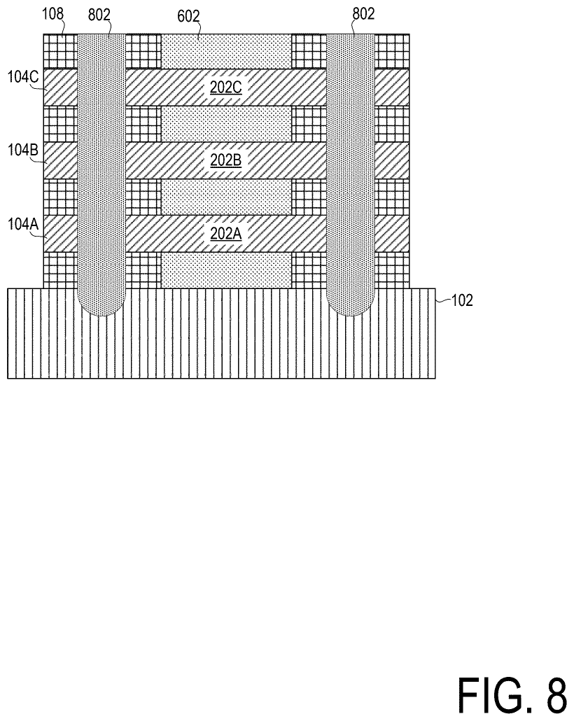

In block 504, trenches 702 for the source/drain regions are created, as shown in FIG. 7. In an illustrative embodiment, the dielectric spacers 108 are disposed around the trenches 702, as shown in the figure. In block 506, the source/drain trenches 702 are filled with a sacrificial material 802, as shown in FIG. 8. The sacrificial material 802 may be any suitable material that can be selectively removed at a later processing step, such as highly doped silicon, doped or undoped silicon-germanium alloys, doped or undoped germanium, amorphous silicon, poly-crystalline silicon, etc. Possible dopants include phosphorous, arsenic, and boron. It should be appreciated that, in an illustrative embodiment, dopants in a lattice that would diffuse at high-temperature processing steps are not used for the sacrificial material 802. Rather, the sacrificial material 802 is a material that either does not have a high dopant concentration or uses dopants that will not diffuse at high-temperature processing steps into the adjacent channel regions 202A-C.

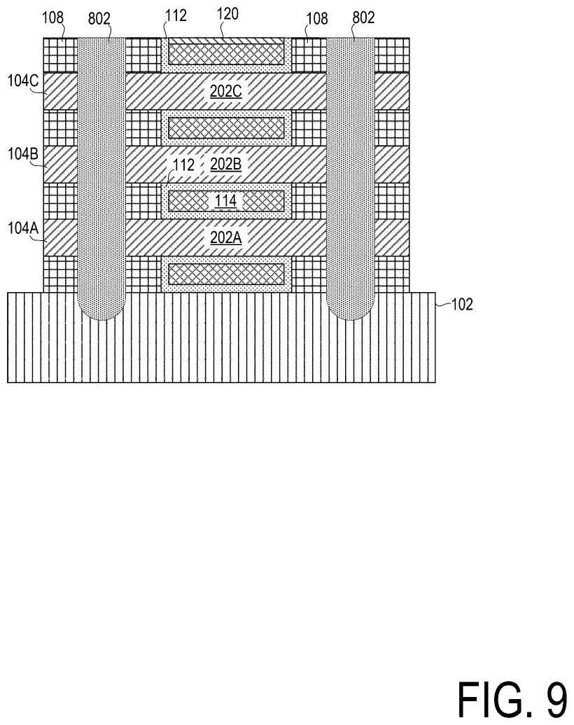

In block 508, the channel regions 202A-C are released by selectively etching the layers of silicon-germanium 602 or other superlattice spacing material. In block 510, the gate dielectric layer 112, gate 114, and conductive material 120 are deposited, as shown in FIG. 9. It should be appreciated that, in an illustrative embodiment, forming the gate dielectric layer 112, gate 114, and conductive material 120 may involve high temperatures, such as temperatures above 450° C. In some embodiments, the temperatures may exceed, e.g., 450-600° C.

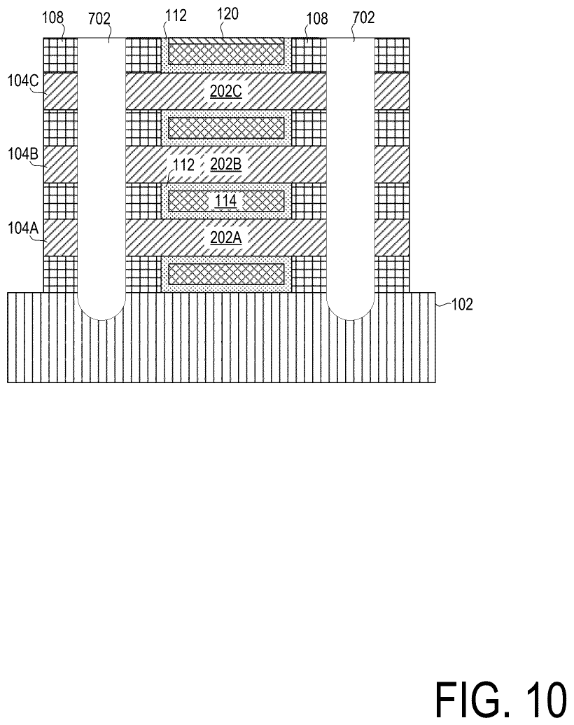

In block 512, the sacrificial material 802 is removed, leaving source/drain trenches 702, as shown in FIG. 10. The sacrificial material 802 is removed using a selective etch that does not remove significant parts of the nanosheets 104A-C, including the channel regions 202A-C.

In block 514, a low-temperature deposition of highly-doped source/drain regions 204 is performed. In an illustrative embodiment, the source/drain regions 204 are silicon. The deposition may be performed at relatively low temperatures, such as temperatures of 400-450° C. or lower.

It should be appreciated that it is difficult to grow doped silicon or germanium or silicon germanium at lower temperatures using standard techniques. In one example of a standard technique, epitaxial growth of silicon is desired only in specific locations, and growth of silicon is generally not desired on, e.g., hardmarks and spacers. In order to selectively epitaxially grow silicon at high temperatures, an etchant such as hydrogen chloride is co-flowed with the deposition gases. The etchant etches away the undesired growth as the desired epitaxial layer is grown. However, at lower temperature, hydrogen chloride is less effective as an etchant, preventing selective growth of silicon. Other possible techniques to attempt to reduce dopant out diffusion include diffusion barriers, ion implantation, alternative dopant precursors, as-grown low-diffusivity films, and/or the like. In each case, the resistivity is not as low as what is achievable with highly-doped epitaxial contacts.

In order to selectively grow silicon at low temperatures, an alternate etch chemistry is used. In an illustrative embodiment, chlorine gas is used as the etchant. However, chlorine gas is not compatible with hydride chemistries, such as hydrogen, phosphine, or silane. In order to keep the chlorine separate from the deposition gases, such as silicon and doping precursors, are first flowed in block 516, forming a thin layer of silicon. The deposition gases are then shut off, and the etchant gas is flowed in block 518. In the illustrative embodiment, the etchant gas is chlorine. In other embodiments, a different gas may be used. The etchant gas preferentially removes the silicon or other deposition from dielectrics such as hardmarks and spacers. With these two steps, a small amount of silicon or other semiconductor can be grown in the trenches 702 without growing it in other locations. The steps are repeated until the desired amount of silicon is grown in the trenches 702.

In block 520, a contact 106 is added to the source/drain regions 204, such as by etching away part of the source/drain regions 204 and depositing the contact 106.

It should be appreciated that the embodiment described above in FIGS. 1-4 and the embodiment described above in regard to FIGS. 5-12 for creating such an embodiment are merely some of the possible embodiments, and other embodiments are envisioned as well. In general, any suitable sacrificial layer may be used and/or low-temperature deposition of highly doped silicon may be used at any suitable stage of manufacture for any suitable purpose, such as creating an interface with a high logarithmic slope of the dopant concentration. Various embodiments are described below in more detail. In some cases, the various features of various embodiments may be used together, as appropriate. For example, the steps described in various embodiments may be used to replace or supplement steps described above in regard to the method 500.

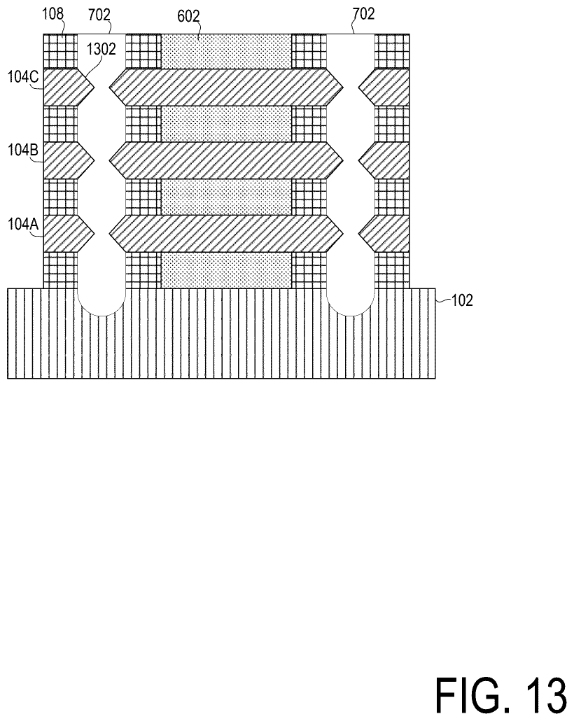

Referring now to FIG. 13, in one embodiment, nubs 1302 may be deposited on the nanosheet 104A-C, after the trenches 702 are formed. The nubs 1302 may extend to a point at one or both ends of the channel regions 202A-C, due to how the nubs 1302 grow on nanosheet 104A-C. In some embodiments, the nubs 1302 may be undoped, lightly doped, or heavily doped, with any suitable dopant. The sacrificial material 802 may then be deposited, the gate dielectric layer 112, gate 114, etc., may then be formed, as described above in regard to FIG. 5. The sacrificial material 802 may then be removed, and the source/drain regions 204 may be deposited using a low-temperature deposition.

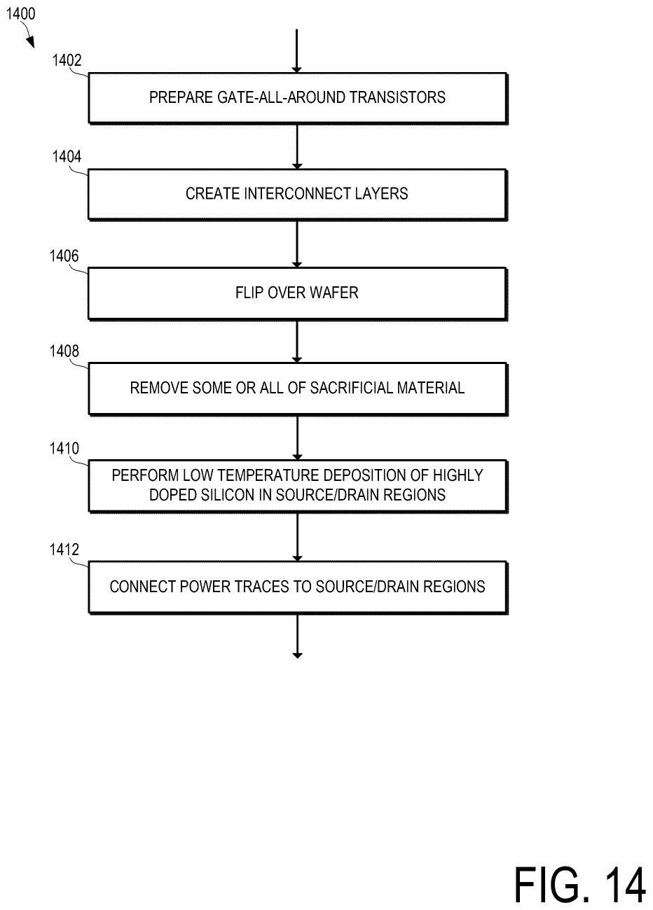

Referring now to FIG. 14, in one embodiment, a flowchart for a method 1400 for creating a transistor is shown. The method 1400 (and/or the methods 2000, 2300 described below) may be performed in a similar manner and using similar techniques as the method 500 described above, which will not be repeated in the interest of clarity. The method 1400 (and/or the methods 2000, 2300) may include any suitable step from method 500 or other methods disclosed herein, as appropriate.

The method 1400 begins in block 1402, in which gate-all-around transistors are prepared, such as by using some or all of the steps of the method 500. In an illustrative embodiment, the gate-all-around transistors are prepared using similar steps to those described in blocks 502-510 of FIG. 5. In an illustrative embodiment, first source/drain region material 1502 is deposited in the trenches 702. The first source/drain region material 1502 may be similar to the sacrificial material 802 or may be similar to the source/drain region 204.

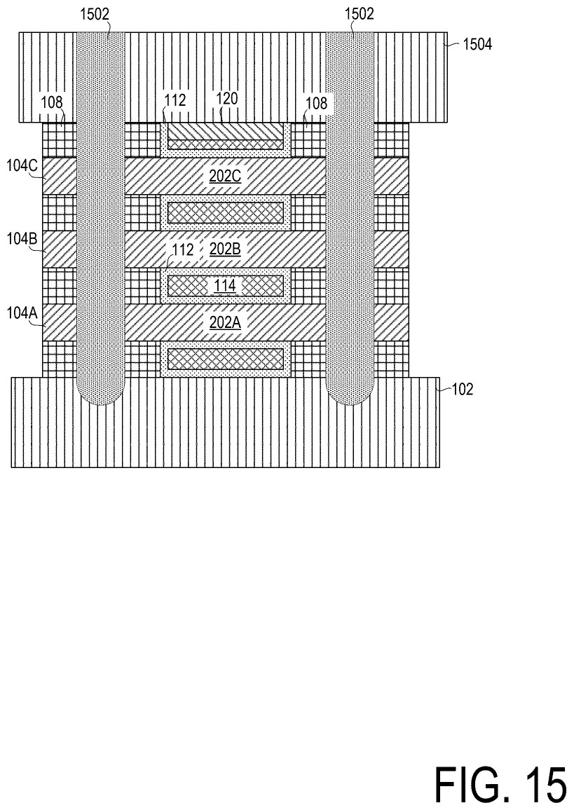

In block 1404, one or more interconnect layers 1504 may be formed above the transistor, as shown in FIG. 15. The interconnect layers 1504 may form connections between the gate 114 and the source/drain region materials 1502 of various transistors.

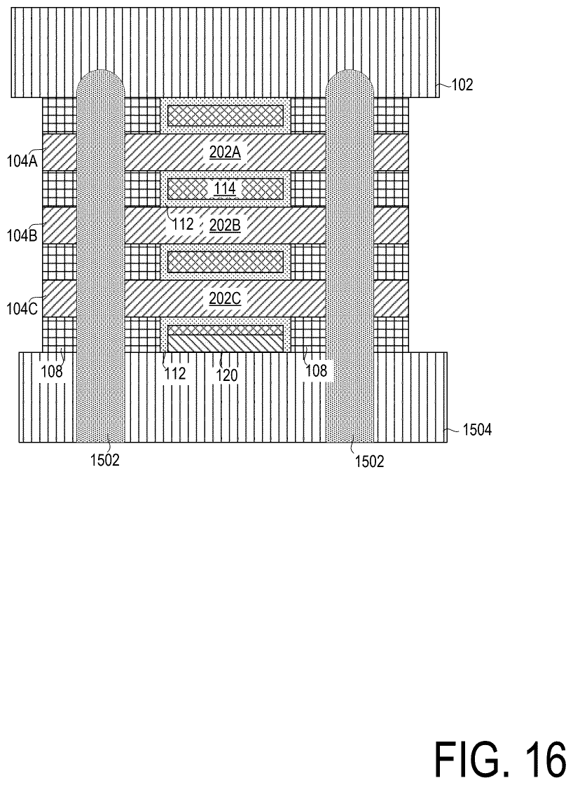

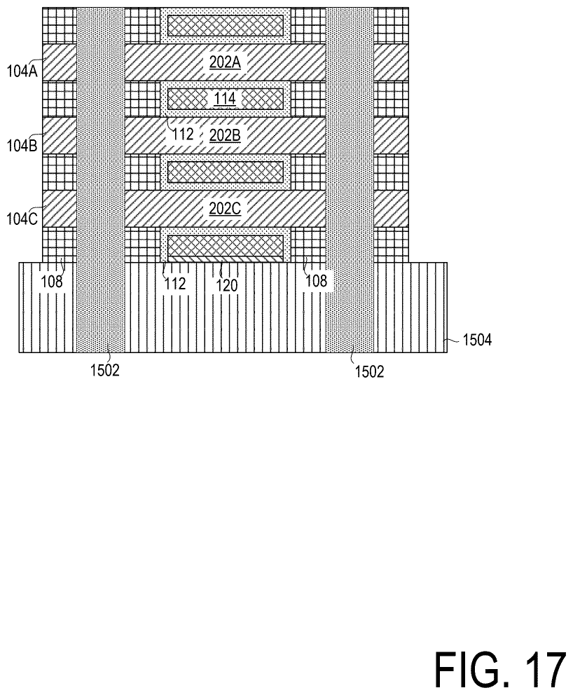

In block 1406, the wafer including the substrate 102 is flipped over, as shown in FIG. 16. The substrate 102 may be thinned or fully removed, as shown in FIG. 17.

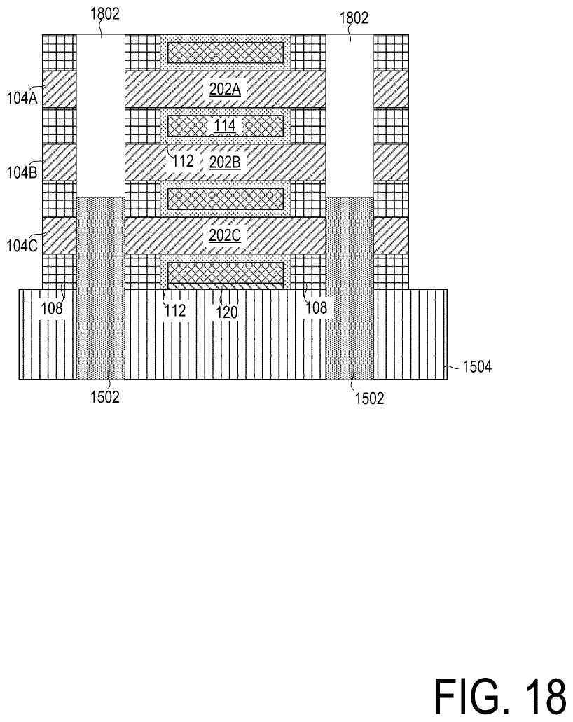

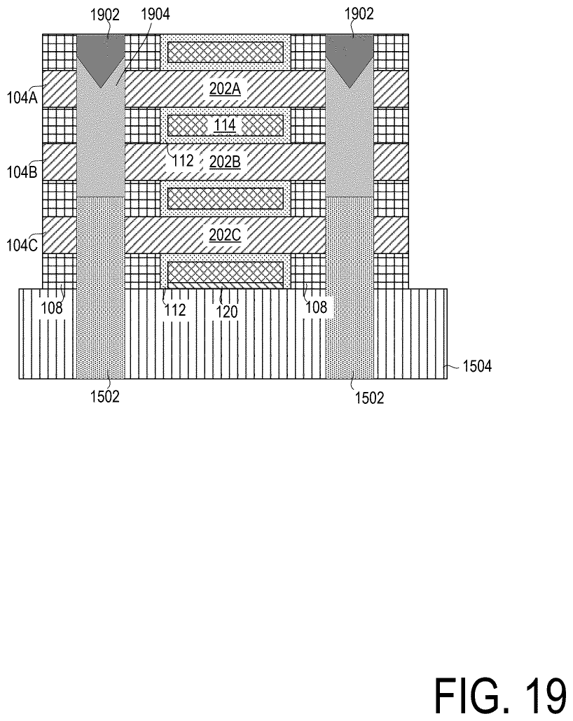

In block 1408, some or all of the first source/drain region material 1502 may be etched away, creating trenches 1802, as shown in FIG. 18. In block 1410, a low-temperature deposition of second source/drain regions 1904 is performed. In an illustrative embodiment, the second source/drain regions 1904 may be similar to the source/drain regions 204 described above. The deposition may be performed at relatively low temperatures, such as temperatures of 400-450° C. or lower. A contact 1902 may be deposited on the second source/drain regions 1904, as shown in FIG. 19.

In block 1412, one or more power traces or power vias may be connected to the contacts 1902 or to the second source/drain regions 1904. It should be appreciated that, in some embodiments, the back side of the die with the transistors may be used to provide power, and the front side may be used to provide interconnects or logic contacts for various logic signals. In some embodiments, the second source/drain regions 1904 may be more highly doped than the first source/drain regions. In embodiments in which power (and therefore, larger currents) are provided by the second source/drain regions 1904, the second source/drain regions 1904 being more highly doped may reduce resistive losses and power consumption overall.

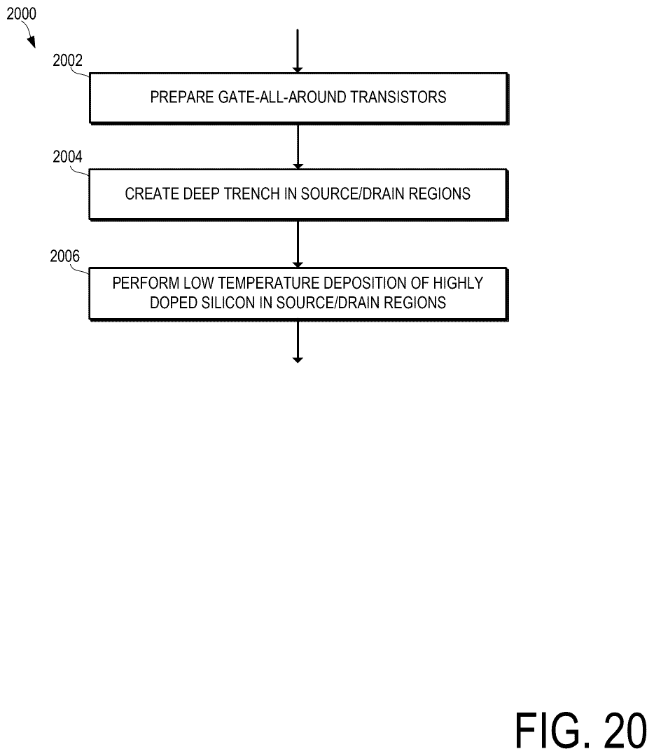

Referring now to FIG. 20, in one embodiment, a flowchart for a method 2000 for creating a transistor is shown. The method 2000 begins in block 2002, in which gate-all-around transistors are prepared, such as by using some or all of the steps of the method 500. In an illustrative embodiment, the gate-all-around transistors are prepared using similar steps to those described in blocks 502-510 of FIG. 5. In an illustrative embodiment, first source/drain region material 2102 is deposited in the trenches 702. The first source/drain region material 2102 may be similar to the sacrificial material 802 or may be similar to the source/drain regions 204. In some embodiments, the first source/drain region material 2102 may be embodied as a low-diffusivity material, such as a material with low-doping concentrations or doped with dopants known to have lower diffusion at elevated temperatures.

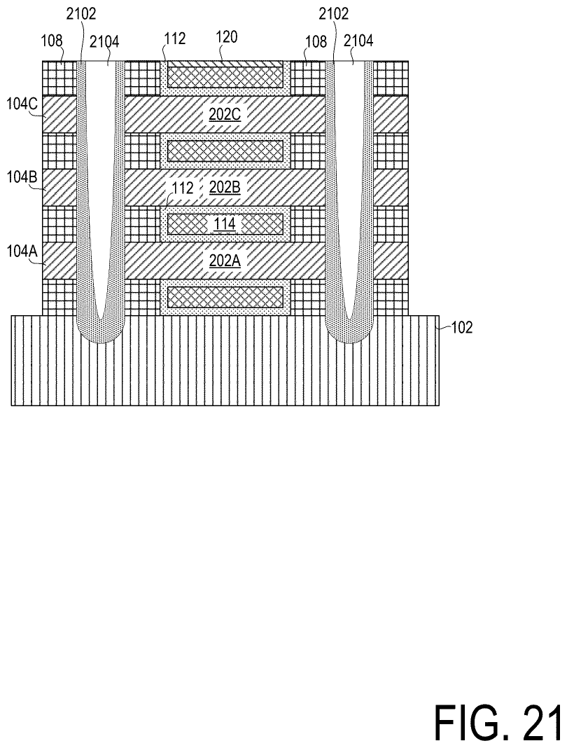

In block 2004, deep trenches 2104 may be formed in the first source/drain region material 2102, as shown in FIG. 21. The deep trenches 2104 may be created using any suitable deep etching technique, such as plasma-based dry etching techniques, reactive ion etching, deep reactive ion etching, laser-assisted etching, focused ion beam, and/or the like.

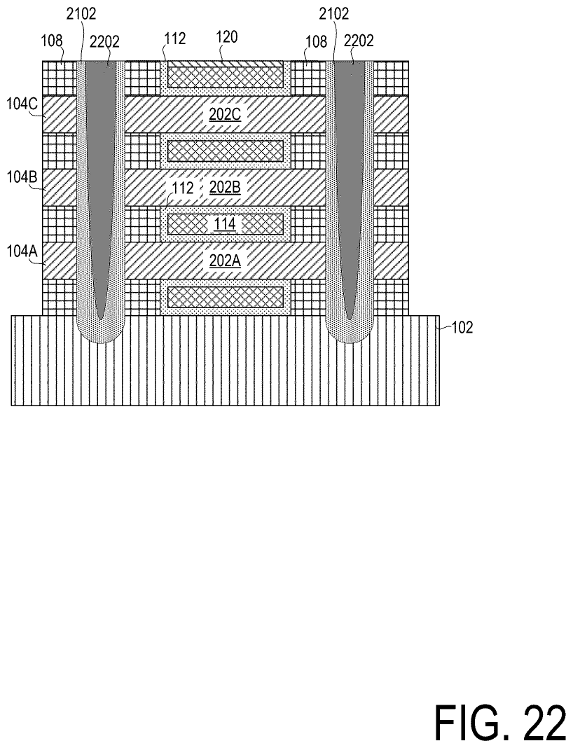

In block 2006, a low-temperature deposition of second source/drain regions 2202 is performed, creating the second source/drain regions 2202 in the deep trenches 2104 and adjacent the first source/drain region material 2102, as shown in FIG. 22. In an illustrative embodiment, the second source/drain regions 2202 may be similar to the source/drain regions 204 described above. The deposition may be performed at relatively low temperatures, such as temperatures of 400-450° C. or lower.

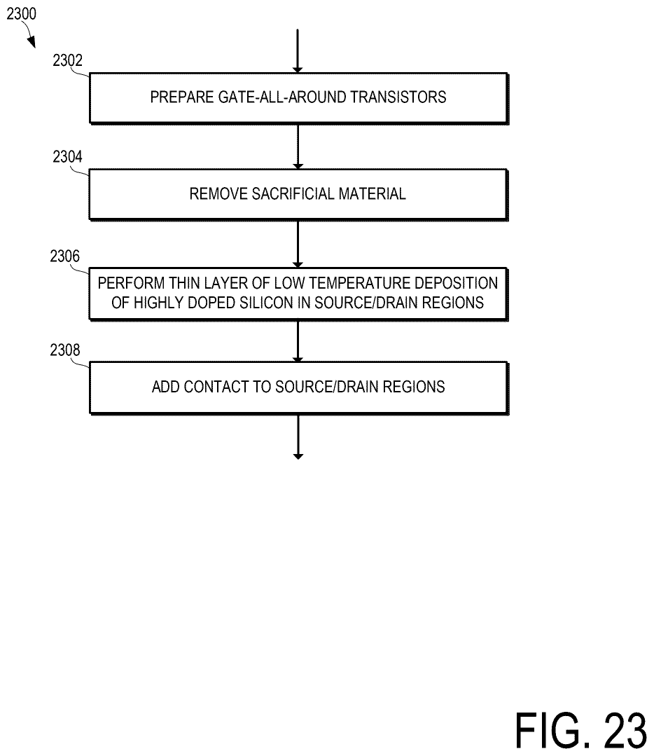

Referring now to FIG. 23, in one embodiment, a flowchart for a method 2300 for creating a transistor is shown. The method 2300 begins in block 2302, in which gate-all-around transistors are prepared, such as by using some or all of the steps of the method 500. In an illustrative embodiment, the gate-all-around transistors are prepared using similar steps to those described in blocks 502-510 of FIG. 5.

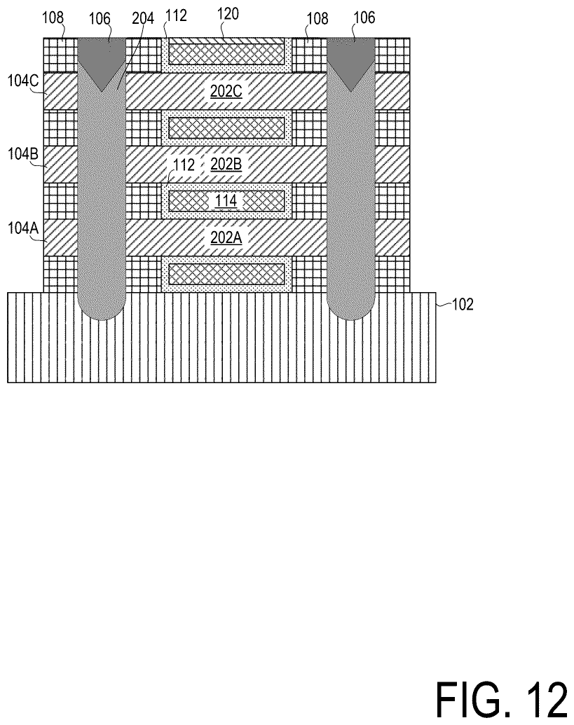

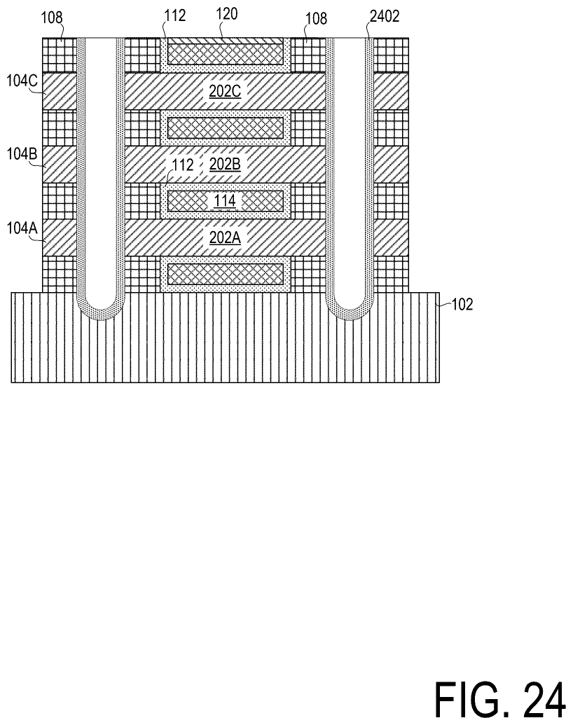

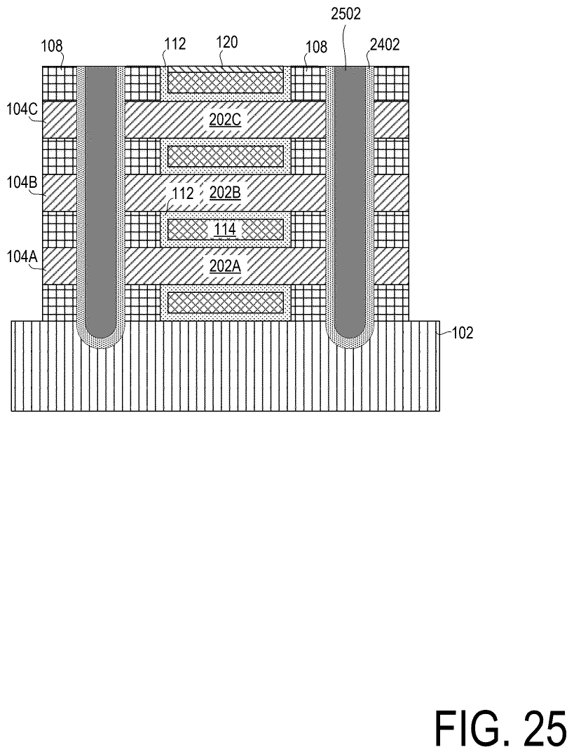

In block 2304, the sacrificial material 802 is removed. In block 2306, a low-temperature deposition of source/drain regions 2402 is performed, creating a thin layer of a source/drain regions 2402, as shown in FIG. 24. As shown in FIG. 24, at a cross-sectional side view, the source/drain regions 2402 have a U shape. The source/drain regions 2402 may be similar to the source/drain regions 204 described above. The source/drain regions 2402 may be grown to any suitable thickness, such as 1-5 nanometers. In block 2308, a contact 2502 is deposited on the source/drain regions 2402, as shown in FIG. 25. The contact 2502 may be similar to the contact 106. It should be appreciated that the contact 2502 has a higher surface area contact with the source/drain regions 2402 compared to that shown in FIG. 12, which may be preferred in some embodiments.

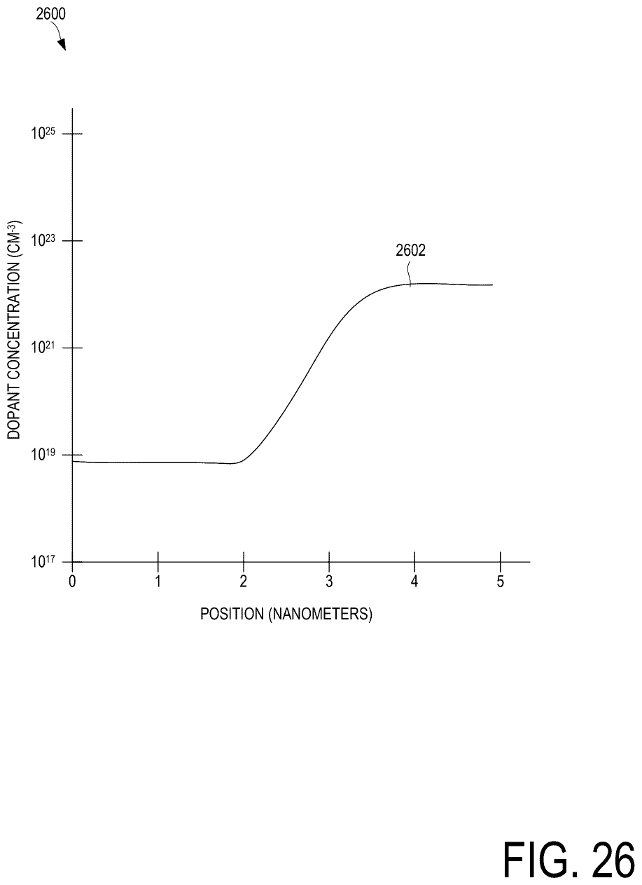

Referring now to FIG. 26, in one embodiment, a plot 2600 shows the dopant concentration 2602 as a function of position for various embodiments of the GAA FETs 100 described herein. The dopant concentration 2602 may be taken at, e.g., an interface between the source/drain region 204 and the channels 202A-C, with the interface centered at about the middle of the dopant concentration transition, or about 3 nanometers in the plot shown. The logarithmic slope of the dopant concentration may be high, such as two orders of magnitude change in dopant concentration in less than one nanometer. For comparison, high-temperature processing steps may reduce the logarithmic slope of the dopant concentration to significantly lower, such as two orders of magnitude change in dopant concentration in ten nanometers. In general, the techniques described herein enable high logarithmic slope of the dopant concentration, such as 0.2-2 orders of magnitude per nanometer. The higher dopant concentration may be any suitable value, such as a dopant concentration of 10¹⁷-10²⁴ cm⁻³, and the lower dopant concentration may be any suitable value, such as 10¹³-10¹⁹ cm⁻³. In general, the difference in dopant concentration between the high dopant concentration and the low dopant concentration may be any suitable amount, such as 1-6 orders of magnitude.

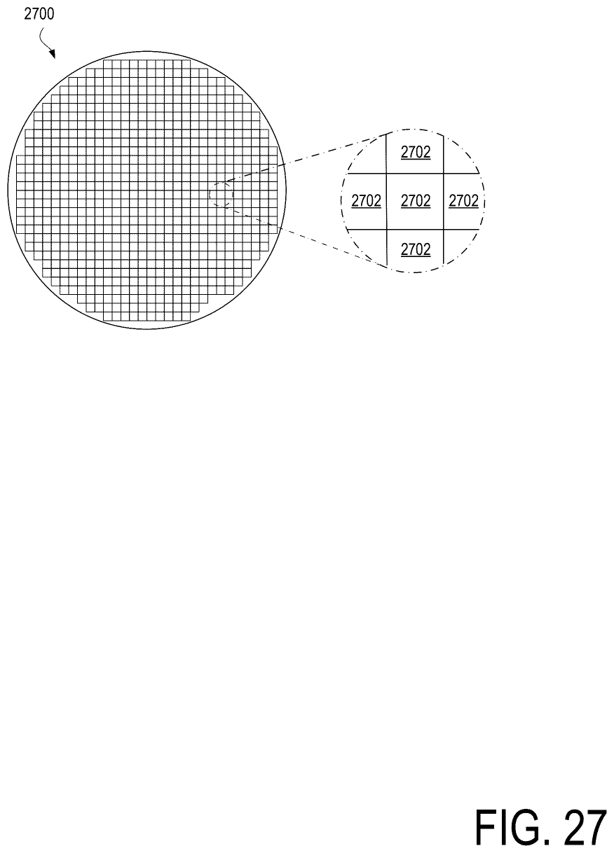

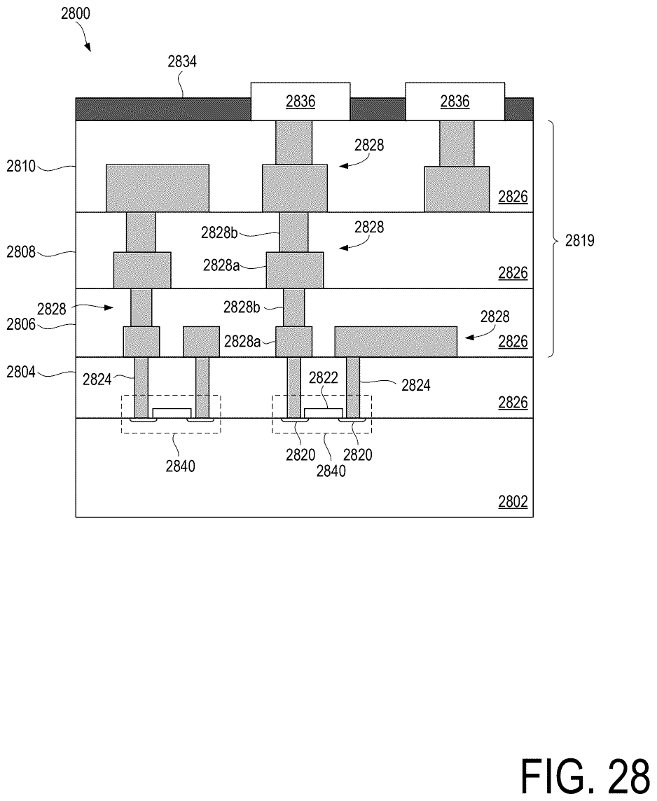

FIG. 27 is a top view of a wafer 2700 and dies 2702 that may be included in any of the microelectronic assemblies disclosed herein (e.g., as any suitable ones of the substrates 102). The wafer 2700 may be composed of semiconductor material and dies 2702 having integrated circuit structures formed on a surface of the wafer 2700. The individual dies 2702 may be a repeating unit of an integrated circuit product that includes any suitable integrated circuit. After the fabrication of the semiconductor product is complete, the wafer 2700 may undergo a singulation process in which the dies 2702 are separated from one another to provide discrete “chips” of the integrated circuit product. The dies 2702 may be any of the substrates 102 disclosed herein. The dies 2702 may include one or more transistors (e.g., transistors 2840 of FIG. 28, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 2700 or the dies 2702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the microelectronic assemblies disclosed herein may be manufactured using a die-to-wafer assembly technique in which some substrates 102 are attached to a wafer 2700 that include others of the substrates 102, and the wafer 2700 is subsequently singulated.

FIG. 28 is a cross-sectional view of an integrated circuit structure 2800 that may be included in any of the microelectronic assemblies disclosed herein (e.g., in any of the substrates 102). Multiple instances of the integrated circuit structure 2800 may be included in the dies 2702 (FIG. 27). The integrated circuit structure 2800 may be formed on a die substrate 2802. The die substrate 2802 may be a semiconductor substrate composed of semiconductor material including, for example, n-type or p-type materials (or a combination of both). The die substrate 2802 may include, for example, a crystalline substrate formed using a bulk silicon or a silicon-on-insulator (SOI) substructure. In some embodiments, the die substrate 2802 can comprise a layer of silicon on top of an SOI layer with bulk silicon below the SOI layer. In some embodiments, the die substrate 2802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2802. Although a few examples of materials from which the die substrate 2802 may be formed are described here, any material that may serve as a foundation for an integrated circuit structure 2800 may be used. The die substrate 2802 may be part of a singulated die (e.g., dies 2702 of FIG. 27) or a wafer (e.g., wafer 2700 of FIG. 27).

The integrated circuit structure 2800 may include device layer 2804 disposed on the die substrate 2802. The device layer 2804 may include features of transistors 2840 (e.g., metal oxide semiconductor field-effect transistors (MOSFETs)) formed on the die substrate 2802. The transistors 2840 may include, for example, source and drain regions (S/D regions 2820), a gate 2822 to control current flow between the S/D regions 2820, and S/D contacts 2824 to route electrical signals to and from the S/D regions 2820. The transistors 2840 may include additional features not depicted for the sake of clarity, such as device isolation regions, gate contacts, and the like. The transistors 2840 are not limited to the type and configuration depicted in FIG. 28 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

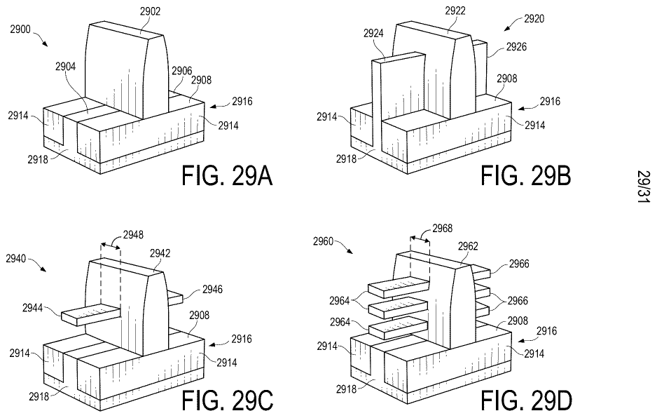

FIGS. 29A-29D are perspective views of example planar, FinFET, gate-all-around, and stacked gate-all-around transistors. The transistors illustrated in FIGS. 29A-29D are formed on a substrate 2916 having a substrate surface 2908 and a bulk region 2918. Isolation regions 2914 separate the source and drain regions of the transistors from other transistors.

FIG. 29A is a perspective view of an example transistor 2900 comprising a gate 2902 that controls current flow between a source region 2904 and a drain region 2906. The transistor 2900 is planar in that the source region 2904, the drain region 2906 and the substrate surface 2908 lie in the same plane.

FIG. 29B is a perspective view of an example transistor 2920 comprising a gate 2922 that controls current flow between a source region 2924 and a drain region 2926. The transistor 2920 is non-planar in that the source region 2924 and the drain region 2926 comprise “fins” that extend upwards from the substrate surface 2908. The transistor 2920 can be referred to as a FinFET. As the gate 2922 encompasses three sides of the fin that extends from the source region 2924 to the drain region 2926, the transistor 2920 can be considered a tri-gate transistor. FIG. 29B illustrates one S/D fin extending through the gate 2922, but multiple S/D fins can extend through the gate of a FinFET transistor.

FIG. 29C is a perspective view of a transistor 2940 comprising a gate 2942 that controls current flow between a source region 2944 and a drain region 2946. The transistor 2940 is non-planar in that the source region 2944 and the drain region 2946 lie in a different plane than the substrate surface 2908. As the gate 2942 encompasses all sides of the channel region of the transistor 2940 that extends from the source region 2944 to the drain region 2946, the transistor 2940 can be referred to as a gate-all-around (GAA) transistor.

FIG. 29D is a perspective view of a transistor 2960 comprising a gate 2962 that controls current flow between multiple elevated source regions 2964 and multiple elevated drain regions 2966. The transistor 2960 is a stacked GAA transistor as the gate controls the flow of current between multiple elevated S/D regions stacked on top of each other. The transistors 2940 and 2960 are considered gate-all-around transistors as the gates encompass all sides of the channel regions of the transistor that extends from the source regions to the drain regions. The transistors 2940 and 2960 can alternatively be referred to as nanowire, nanosheet, or nanoribbon transistors depending on the width (e.g., widths 2948 and 2968 of transistors 2940 and 2960, respectively) of the channel regions extending through the gate.

Returning to FIG. 28, transistors 2840 may include a gate 2822 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 29B, the gate electrode may have an upside-down U-shape that includes a top portion substantially parallel to the surface of the die substrate 2802 and two side portions that are substantially perpendicular to the top surface of the die substrate 2802. In other embodiments, such as the planar FET illustrated in FIG. 29A, at least one of the metal layers that form the gate electrode may be a planar layer that is substantially parallel to the top surface of the die substrate 2802 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 2820 may be formed within the die substrate 2802 adjacent to the gate 2822 of transistors 2840. The S/D regions 2820 may be formed using an implantation/diffusion process or an etching/deposition process, for example. In the former process, dopants such as boron, aluminum, antimony, phosphorous, or arsenic may be ion-implanted into the die substrate 2802 to form the S/D regions 2820. An annealing process that activates the dopants and causes them to diffuse further into the die substrate 2802 may follow the ion implantation process. In the latter process, the die substrate 2802 may first be etched to form recesses at the locations of the S/D regions 2820. An epitaxial deposition process may then be carried out to fill the recesses with material that is used to fabricate the S/D regions 2820. In some implementations, the S/D regions 2820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2820 may be formed using one or more alternate semiconductor materials such as germanium or a group III-V material or alloy. In further embodiments, one or more layers of metal and/or metal alloys may be used to form the S/D regions 2820.

Electrical signals, such as power and/or information-carrying signals (e.g., input/output (I/O) signals, may be routed to and/or from devices (e.g., transistors 2840) of the device layer 2804 through one or more interconnect layers disposed on the device layer 2804 (illustrated in FIG. 28 as interconnect layers 2806-2810). For example, electrically conductive features of the device layer 2804 (e.g., the gate 2822 and the S/D contacts 2824) may be electrically coupled with interconnect structures 2828 of the interconnect layers 2806-2810. The one or more interconnect layers 2806-2810 may form a metallization stack 2819 (which can also be referred to as an “ILD stack” (inter-layer dielectric stack)) of the integrated circuit structure 2800.

The interconnect structures 2828 may be arranged within the interconnect layers 2806-2810 to route electrical signals according to a wide variety of designs; in particular, the arrangement is not limited to the particular configuration of interconnect structures 2828 depicted in FIG. 28. Although a particular number of interconnect layers 2806-2810 is depicted in FIG. 28, embodiments of the present disclosure include integrated circuit structures having more or fewer interconnect layers than depicted.

In some embodiments, the interconnect structures 2828 may include traces or lines 2828a and/or vias 2828b filled with an electrically conductive material such as a metal. The lines 2828a may be arranged to route electrical signals in a direction of a plane that is substantially parallel with a surface of the die substrate 2802 upon which the device layer 2804 is formed. For example, the lines 2828a may route electrical signals in a direction in and out of the page and/or in a direction across the page from the perspective of FIG. 28. The vias 2828b may be arranged to route electrical signals in a direction of a plane that is substantially perpendicular to the surface of the die substrate 2802 upon which the device layer 2804 is formed. In some embodiments, lines 2828a of different interconnect layers 2806-2810 are electrically coupled by vias 2828b.

The interconnect layers 2806-2810 may include a dielectric material 2826 within which the interconnect structures 2828 are disposed, as shown in FIG. 28. In some embodiments, dielectric material 2826 in different ones of the interconnect layers 2806-2810 may have different compositions; in other embodiments, the composition of the dielectric material 2826 between different interconnect layers 2806-2810 may be the same. The device layer 2804 may include a dielectric material 2826 within which the transistors 2840 are disposed and upon which a bottom layer of the metallization stack is located. The dielectric material 2826 that is part of the device layer 2804 may have a different composition than the dielectric material 2826 included in the interconnect layers 2806-2810; in other embodiments, the composition of the dielectric material 2826 in the device layer 2804 may be the same as a dielectric material 2826 included in any one of the interconnect layers 2806-2810.

A first interconnect layer 2806 (which can be referred to as a Metal 1 or “M1” layer) may be formed directly on the device layer 2804. In some embodiments, the first interconnect layer 2806 may include lines 2828a and/or vias 2828b, as shown. The lines 2828a of the first interconnect layer 2806 may be coupled with contacts (e.g., the S/D contacts 2824) of the device layer 2804. The vias 2828b of the first interconnect layer 2806 may be coupled with the lines 2828a of a second interconnect layer 2808.

The second interconnect layer 2808 (which can be referred to as a Metal 2 or “M2” layer) may be formed directly on the first interconnect layer 2806. In some embodiments, the second interconnect layer 2808 may include vias 2828b to couple the lines 2828a of the second interconnect layer 2808 with the lines 2828a of a third interconnect layer 2810. Although the lines 2828a and the vias 2828b are structurally delineated with a line within individual interconnect layers for the sake of clarity, the lines 2828a and the vias 2828b may be structurally and/or materially contiguous (e.g., simultaneously filled during a dual-damascene process) in some embodiments.

The third interconnect layer 2810 (which can be referred to as a Metal 3 or “M3” layer) (and additional interconnect layers, as desired) may be formed in succession on the second interconnect layer 2808 according to similar techniques and configurations described in connection with the second interconnect layer 2808 or the first interconnect layer 2806. In some embodiments, the interconnect layers that are “higher up” in the metallization stack 2819 in the integrated circuit structure 2800 (i.e., farther away from the device layer 2804) may be thicker than the interconnect layers that are lower in the metallization stack 2819, with lines 2828a and vias 2828b in the higher interconnect layers being thicker than those in the lower interconnect layers.

The integrated circuit structure 2800 may include a solder resist material 2834 (e.g., polyimide or similar material) and conductive contacts 2836 formed on the stack of interconnect layers 2806-2810. In FIG. 28, the conductive contacts 2836 are illustrated as taking the form of bond pads. The conductive contacts 2836 may be electrically coupled with interconnect structures 2828 of the top-most layer in the metallization stack 2819 and configured to route electrical signals between the transistors 2840 and components external to the integrated circuit structure 2800. For example, solder bonds may be formed on the conductive contacts 2836 to mechanically and/or electrically couple an integrated circuit component comprising the integrated circuit structure 2800 with another component (e.g., a printed circuit board). The integrated circuit structure 2800 may include additional or alternate structures to route electrical signals from the interconnect layers 2806-2810; for example, the conductive contacts 2836 may include other analogous features (e.g., posts) that can route the electrical signals between the transistors 2840 and external components.

In some embodiments in which the integrated circuit structure 2800 is part of a double-sided die (e.g., like the substrate 102), the integrated circuit structure 2800 may include a second metallization stack (not shown) located on the opposite side of the die substrate 2802 from the device layer 2804. This second metallization stack may include multiple interconnect layers as discussed above with reference to the interconnect layers 2806-2810. Through-silicon vias (TSVs) that extend through the die substrate 2802 can provide electrically conductive pathways from the transistors 2840 to the second metallization stack and the second metallizaton stack can electrically couple the TSVs to additional conductive contacts (not shown) located on the opposite side of the integrated circuit structure 2800 from the conductive contacts 2836.

In some embodiments, TSVs extending through the die substrate 2802 can be used for routing power and ground signals from conductive contacts located on the opposite side of the integrated circuit structure 2800 from the conductive contacts 2836 to the transistors 2840 and any other components integrated into the integrated circuit structure 2800, and the metallization stack 2819 can be used to route information-carrying signals from the conductive contacts 2836 to transistors 2840 and any other components integrated into the integrated circuit structure 2800. Put another way, the routing of power and ground signals to the transistors 2840 can be separated (via a back-side or bottom-side metallizaton stack and TSVs) from the routing of information-carrying signals to the transistors. The power and ground signals are provided by a back-side or bottom-side metallization stack and TSVs, and information-carrying signals are provide by a top-side metallization stack (e.g., metallization stack 2819).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

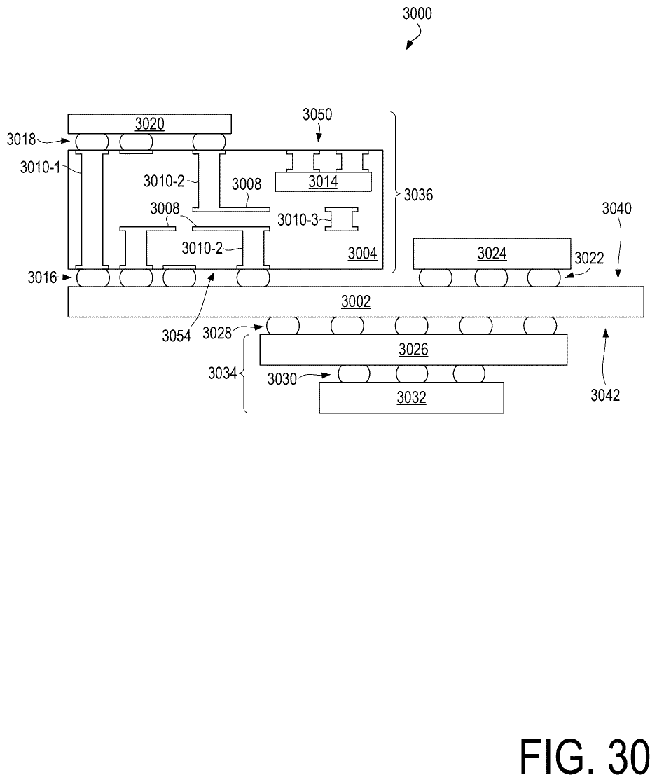

FIG. 30 is a cross-sectional view of an integrated circuit device assembly 3000 that may include any of the microelectronic assemblies disclosed herein. In some embodiments, the integrated circuit device assembly 3000 may include any of the GAA FETs 100. The integrated circuit device assembly 3000 includes a number of components disposed on a circuit board 3002 (which may be a motherboard, system board, mainboard, etc.). The integrated circuit device assembly 3000 includes components disposed on a first face 3040 of the circuit board 3002 and a second face 3042 of the circuit board 3002, the second face 3042 opposing the first face 3040. Generally, components may be disposed on either or both of the first face 3040 and the second face 3042 of the circuit board 3002. Any of the integrated circuit components discussed below with reference to the integrated circuit device assembly 3000 may include any suitable ones of the embodiments of the GAA FETs 100 disclosed herein.

In some embodiments, the circuit board 3002 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 3002. In other embodiments, the circuit board 3002 may be a non-PCB substrate.

The integrated circuit device assembly 3000 illustrated in FIG. 30 includes a package-on-interposer structure 3036 coupled to the first face 3040 of the circuit board 3002 by coupling components 3016. The coupling components 3016 may electrically and mechanically couple the package-on-interposer structure 3036 to the circuit board 3002 and may include solder balls (as shown in FIG. 30), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 3016 may serve as the coupling components illustrated or described for any substrate assembly or substrate assembly components described herein (e.g., integrated circuit components), as appropriate.

The package-on-interposer structure 3036 may include an integrated circuit component 3020 coupled to an interposer 3004. The interposer 3004 may provide an intervening substrate used to bridge the circuit board 3002 and the integrated circuit component 3020. The integrated circuit component 3020 is coupled to the interposer 3004 by coupling components 3018. The coupling components 3018 may take any suitable form, such as the forms discussed above with reference to the coupling components 3016. Although FIG. 30 shows just one integrated circuit component attached to the interposer, multiple integrated circuit components may be coupled to the interposer 3004. Additional interposers may be coupled to the interposer 3004.

The integrated circuit component 3020 may be a packaged or unpacked integrated circuit product that includes one or more integrated circuit dies (e.g., the die 2702 of FIG. 27, a die comprising the integrated circuit structure 2800 of FIG. 28) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 3020, a single monolithic integrated circuit die comprises solder bumps attached to contacts on the die. The solder bumps allow the die to be directly attached to the interposer 3004. The integrated circuit component 3020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 3020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 3020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 3020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 3004 may spread connections to a wider or narrower pitch or reroute a connection to a different connection. For example, the interposer 3004 may couple coupling components 3018 having a first pitch to coupling components 3016 having a wider pitch than the first pitch. In the embodiment illustrated in FIG. 30, the integrated circuit component 3020 and the circuit board 3002 are attached to opposing sides of the interposer 3004. In other embodiments, the integrated circuit component 3020 and the circuit board 3002 may be attached to a same side of the interposer 3004. In some embodiments, three or more components may be interconnected by way of the interposer 3004.

In some embodiments, the interposer 3004 may be formed as a PCB, including multiple metal layers separated from one another by layers of dielectric material and interconnected by electrically conductive vias. In some embodiments, the interposer 3004 may be formed of an epoxy resin, a fiberglass-reinforced epoxy resin, an epoxy resin with inorganic fillers, a ceramic material, or a polymer material such as polyimide. In some embodiments, the interposer 3004 may be formed of alternate rigid or flexible materials that may include the same materials described above for use in a semiconductor substrate, such as silicon, germanium, and other group III-V and group IV materials. The interposer 3004 may include metal interconnects 3008 and vias, including but not limited to through hole vias 3010-1 (that extend from a first face 3050 of the interposer 3004 to a second face 3054 of the interposer 3004), blind vias 3010-2 (that extend from the first face 3050 or the second face 3054 of the interposer 3004 to an internal metal layer), and buried vias 3010-3 (that connect internal metal layers).

In some embodiments, the interposer 3004 can comprise a silicon interposer. Through silicon vias (TSV) extending through the silicon interposer can connect connections on a first face of a silicon interposer to an opposing second face of the silicon interposer. In some embodiments, an interposer 3004 comprising a silicon interposer can further comprise one or more routing layers to route connections on a first face of the interposer 3004 to an opposing second face of the interposer 3004.

In some embodiments the interposer 3004, as well as the circuit board 3002, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 3004 or circuit board 3002 to the glass layer. The glass layer can comprise through-glass vias (TGVs) that extend through the glass layer to provide electrically conductive paths through the glass core, glass substrate, or glass layer.

The interposer 3004 may further include embedded devices 3014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3004. The package-on-interposer structure 3036 may take the form of any of the package-on-interposer structures known in the art.

The integrated circuit device assembly 3000 may include an integrated circuit component 3024 coupled to the first face 3040 of the circuit board 3002 by coupling components 3022. The coupling components 3022 may take the form of any of the embodiments discussed above with reference to the coupling components 3016, and the integrated circuit component 3024 may take the form of any of the embodiments discussed above with reference to the integrated circuit component 3020.

The integrated circuit device assembly 3000 illustrated in FIG. 30 further includes a package-on-package structure 3034 coupled to the second face 3042 of the circuit board 3002 by coupling components 3028. The package-on-package structure 3034 may include an integrated circuit component 3026 and an integrated circuit component 3032 coupled together by coupling components 3030 such that the integrated circuit component 3026 is disposed between the circuit board 3002 and the integrated circuit component 3032. The coupling components 3028 and 3030 may take the form of any of the embodiments of the coupling components 3016 discussed above, and the integrated circuit components 3026 and 3032 may take the form of any of the embodiments of the integrated circuit component 3020 discussed above. The package-on-package structure 3034 may be configured in accordance with any of the package-on-package structures known in the art.

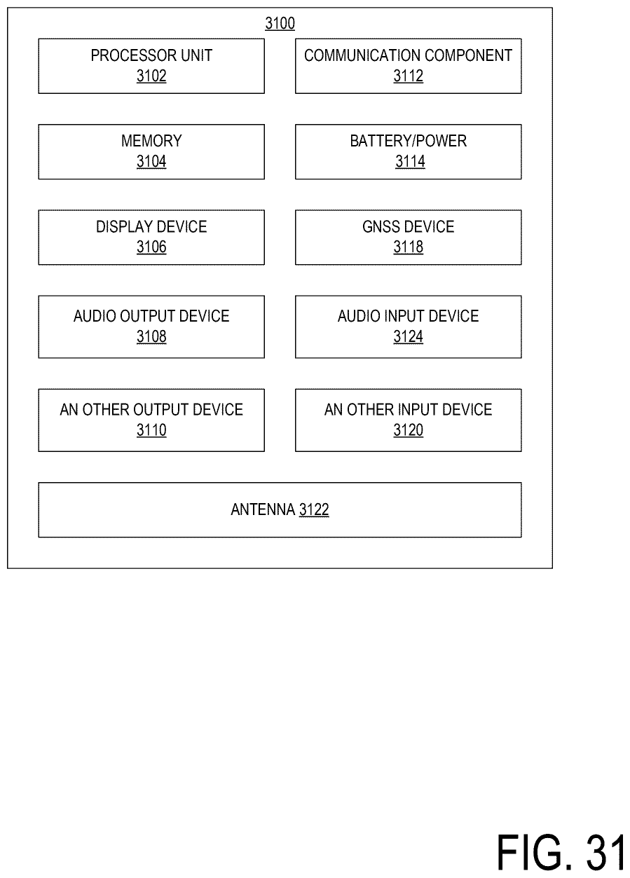

FIG. 31 is a block diagram of an example electrical device 3100 that may include any of the microelectronic assemblies disclosed herein. For example, any suitable ones of the components of the electrical device 3100 may include one or more of the integrated circuit device assembly 3000, integrated circuit component 3020, or integrated circuit structure 2800, integrated circuit dies 2702 disclosed herein, and may be arranged in any of the microelectronic assemblies disclosed herein. A number of components are illustrated in FIG. 31 as included in the electrical device 3100, but any one or more of these components may be omitted or duplicated, as suitable for the application. In some embodiments, some or all of the components included in the electrical device 3100 may be attached to one or more motherboards mainboards, or system boards. In some embodiments, one or more of these components are fabricated onto a single system-on-a-chip (SoC) die.

Additionally, in various embodiments, the electrical device 3100 may not include one or more of the components illustrated in FIG. 31, but the electrical device 3100 may include interface circuitry for coupling to the one or more components. For example, the electrical device 3100 may not include a display device 3106, but may include display device interface circuitry (e.g., a connector and driver circuitry) to which a display device 3106 may be coupled. In another set of examples, the electrical device 3100 may not include an audio input device 3124 or an audio output device 3108, but may include audio input or output device interface circuitry (e.g., connectors and supporting circuitry) to which an audio input device 3124 or audio output device 3108 may be coupled.

The electrical device 3100 may include one or more processor units 3102. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 3102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3100 may include a memory 3104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3104 may include memory that is located on the same integrated circuit die as the one or more processor units 3102. This memory may be used as cache memory (e.g., Level 1 (L1), Level 2 (L2), Level 3 (L3), Level 4(L 4 ), Last Level Cache (LLC)) and may include embedded dynamic random-access memory (eDRAM) or spin transfer torque magnetic random-access memory (STT-MRAM).

In some embodiments of the electrical device 3100, a first one of the one or more processor units 3102 can be heterogeneous or asymmetric to a second one of the one or more processor units 3102 in the electrical device 3100. There can be a variety of differences between the one or more processor units 3102 in a system in terms of a spectrum of metrics of merit including architectural, microarchitectural, thermal, power consumption characteristics, and the like. These differences can effectively manifest themselves as asymmetry and heterogeneity among the one or more processor units 3102 in the electrical device 3100.

In some embodiments, the electrical device 3100 may include a communication component 3112. For example, the communication component 3112 can manage wireless communications for the transfer of data to and from the electrical device 3100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3112 may operate in accordance with other wireless protocols in other embodiments. The electrical device 3100 may include an antenna 3122 to facilitate wireless communications and/or to receive other wireless communications (such as AM or FM radio transmissions).

In some embodiments, the communication component 3112 may manage wired communications, such as electrical, optical, or any other suitable communication protocols (e.g., IEEE 802.3 Ethernet standards). In some embodiments, the electrical device 3100 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 3100 may include battery/power circuitry 3114. The battery/power circuitry 3114 may include one or more energy storage devices (e.g., batteries or capacitors) and/or circuitry for coupling components of the electrical device 3100 to an energy source separate from the electrical device 3100 (e.g., AC line power).

The electrical device 3100 may include a display device 3106 (or corresponding interface circuitry, as discussed above). The display device 3106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3100 may include an audio output device 3108 (or corresponding interface circuitry, as discussed above). The audio output device 3108 may include any embedded or wired or wirelessly connected external device that generates an audible indicator, such as speakers, headsets, or earbuds.

The electrical device 3100 may include an audio input device 3124 (or corresponding interface circuitry, as discussed above). The audio input device 3124 may include any embedded or wired or wirelessly connected device that generates a signal representative of a sound, such as microphones, microphone arrays, or digital instruments (e.g., instruments having a musical instrument digital interface (MIDI) output). The electrical device 3100 may include a Global Navigation Satellite System device (GNSS) (or corresponding interface circuitry, as discussed above), such as a Global Positioning System (GPS) device. The GNSS device 3118 may be in communication with a satellite-based system and may determine a geolocation of the electrical device 3100 based on information received from one or more GNSS satellites, as known in the art.

The electrical device 3100 may include another output device 3110 (or corresponding interface circuitry, as discussed above). Examples of the other output device 3110 may include an audio codec, a video codec, a printer, a wired or wireless transmitter for providing information to other devices, or an additional storage device.

The electrical device 3100 may include another input device 3120 (or corresponding interface circuitry, as discussed above). Examples of the other input device 3120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3100 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3100 may be any other electronic device that processes data. In some embodiments, the electrical device 3100 may comprise multiple discrete physical components. Given the range of devices that the electrical device 3100 can be manifested as in various embodiments, in some embodiments, the electrical device 3100 can be referred to as a computing device or a computing system.

### EXAMPLES

Illustrative examples of the technologies disclosed herein are provided below. An embodiment of the technologies may include any one or more, and any combination of, the examples described below.

Example 1 includes a device comprising a gate-all-around transistor comprising a first source or drain region; a second source or drain region; and a channel region, wherein the channel region is adjacent the first source or drain region and the second source or drain region, wherein an interface of the first source or drain region and the channel region has a dopant concentration gradient, wherein the dopant concentration gradient has a logarithmic slope of the dopant concentration of at least one order of magnitude per nanometer.

Example 2 includes the subject matter of Example 1, and wherein the first source or drain region has a first dopant concentration level at a first position, wherein the channel region has a second dopant concentration level at a second position, wherein the first dopant concentration level is at least two orders of magnitude higher than the second dopant concentration level, wherein the second position is less than two nanometers away from the first position.

Example 3 includes the subject matter of any of Examples 1 and 2, and wherein the gate-all-around transistor is an NMOS transistor, wherein an interface of the first source or drain region and the channel region has a phosphorous dopant concentration gradient, wherein the phosphorous dopant concentration gradient has a logarithmic slope of the dopant concentration of at least one order of magnitude per nanometer.

Example 4 includes the subject matter of any of Examples 1-3, and wherein a phosphorous dopant concentration in the first source or drain region is more than 5 times 1019 per cubic centimeter, wherein a phosphorous dopant concentration in the channel region is less than 5 times 1018 per cubic centimeter.

Example 5 includes the subject matter of any of Examples 1-4, and wherein the gate-all-around transistor further comprises a third source or drain region and a fourth source or drain region, wherein the third source or drain region is adjacent the first source or drain region, wherein the fourth source or drain region is adjacent the second source or drain region, wherein the first source or drain region has a higher dopant concentration than the third source or drain region, wherein the second source or drain region has a higher dopant concentration than the fourth source or drain region, wherein a first back side power contact is adjacent the first source or drain region, wherein a second back side power contact is adjacent the second source or drain region, wherein a first front side logic contact is adjacent the third source or drain region, wherein a second front side logic contact is adjacent the fourth source or drain region.

Example 6 includes the subject matter of any of Examples 1-5, and wherein the channel region comprises one or more nubs extending to a point at one or both ends of the channel region.

Example 7 includes the subject matter of any of Examples 1-6, and wherein, at a cross-sectional side view, the first source or drain region has a U shape, wherein a thickness of the first source or drain region is between 1 and 3 nanometers, wherein, at a cross-sectional side view, the second source or drain region has a U shape, wherein a thickness of the second source or drain region is between 1 and 3 nanometers.

Example 8 includes the subject matter of any of Examples 1-7, and further including a processor, wherein the processor comprises the gate-all-around transistor.

Example 9 includes the subject matter of any of Examples 1-8, and further including one or more memory devices communicatively coupled to the processor.

Example 10 includes a device comprising a transistor comprising a first region, wherein the first region has a first dopant concentration; a second region, wherein the second region has a second dopant concentration; and an interface region, the interface region between the first region and the second region and adjacent the first region and the second region, wherein the interface region has a dopant concentration gradient from the first region to the second region, wherein the dopant concentration gradient has a logarithmic slope of the dopant concentration of at least one order of magnitude per nanometer, wherein at least part of the interface region has a dopant concentration less than 1019 per cubic centimeter and at least part of the interface region has a dopant concentration more than 1019 per cubic centimeter.

Example 11 includes the subject matter of Example 10, and wherein the first region is a source/drain region, wherein the second region is a channel region, wherein the source/drain region has a first dopant concentration level at a first position, wherein the channel region has a second dopant concentration level at a second position, wherein the first dopant concentration level is at least two orders of magnitude higher than the second dopant concentration level, wherein the second position is less than two nanometers away from the first position.

Example 12 includes the subject matter of any of Examples 10 and 11, and wherein the transistor is an NMOS gate-all-around transistor, wherein the interface region has a phosphorous dopant concentration gradient, wherein the phosphorous dopant concentration gradient has a logarithmic slope of the dopant concentration of at least one order of magnitude per nanometer.

Example 13 includes the subject matter of any of Examples 10-12, and wherein a phosphorous dopant concentration in the first region is more than 5 times 1019 per cubic centimeter, wherein a phosphorous dopant concentration in the second region is less than 5 times 1018 per cubic centimeter.

Example 14 includes the subject matter of any of Examples 10-13, and wherein the first region is a first source or drain region, wherein the second region is a second source or drain region, wherein the transistor further comprises a channel region, the second source or drain region adjacent the channel region.

Example 15 includes the subject matter of any of Examples 10-14, and wherein the second region comprises one or more nubs extending to a point at one or both ends of the second region.

Example 16 includes the subject matter of any of Examples 10-15, and wherein, at a cross-sectional side view, the first region has a U shape, wherein a thickness of the first region is between 1 and 3 nanometers.

Example 17 includes the subject matter of any of Examples 10-16, and further including a processor, wherein the processor comprises the transistor.

Example 18 includes the subject matter of any of Examples 10-17, and further including one or more memory devices communicatively coupled to the processor.

Example 19 includes a method for creating a transistor, the method comprising performing one or more high temperature semiconductor processing steps at a temperature about 500° C.; and after performing the one or more high temperature semiconductor processing steps, growing a silicon region at a temperature of less than 450° C., the silicon region comprising a dopant concentration of at least 1020 per cubic centimeter, wherein growing the silicon region comprises alternately flowing deposition gases and flowing an etchant gas.

Example 20 includes the subject matter of Example 19, and wherein the etchant gas comprises chlorine.

Example 21 includes the subject matter of any of Examples 19 and 20, and wherein performing the one or more high temperature semiconductor processing steps comprises depositing a gate dielectric, a gate, or both the gate dielectric and the gate.

Example 22 includes the subject matter of any of Examples 19-21, and further including depositing a sacrificial material before performing the one or more high temperature semiconductor processing steps; and removing the sacrificial material after performing the one or more high temperature semiconductor processing steps and before growing the silicon region.

Example 23 includes the subject matter of any of Examples 19-22, and wherein an interface of the silicon region and an adjacent channel region has a dopant concentration gradient, wherein the dopant concentration gradient has a logarithmic slope of the dopant concentration of at least one order of magnitude per nanometer.

Example 24 includes the subject matter of any of Examples 19-23, and wherein the adjacent channel region has a first dopant concentration level at a first position, wherein the silicon region has a second dopant concentration level at a second position, wherein the first dopant concentration level is at least two orders of magnitude higher than the second dopant concentration level, wherein the second position is less than two nanometers away from the first position.

Example 25 includes the subject matter of any of Examples 19-24, and further including creating a gate-all-around transistor, wherein creating the gate-all-around transistor comprises performing the one or more high temperature semiconductor processing steps and growing the silicon region.

Example 26 includes the subject matter of any of Examples 19-25, and wherein the gate-all-around transistor is an NMOS transistor, wherein an interface of the silicon region and an adjacent channel region has a phosphorous dopant concentration gradient, wherein the phosphorous dopant concentration gradient has a logarithmic slope of the dopant concentration of at least one order of magnitude per nanometer.

Example 27 includes the subject matter of any of Examples 19-26, and wherein a phosphorous dopant concentration in the silicon region is more than 5 times 1019 per cubic centimeter, wherein a phosphorous dopant concentration in a channel region adjacent the silicon region is less than 5 times 1018 per cubic centimeter.

Example 28 includes the subject matter of any of Examples 19-27, and wherein, at a cross-sectional side view, the silicon region has a U shape, wherein a thickness of the silicon region is between 1 and 3 nanometers.

1. A device comprising:
a gate-all-around transistor comprising:
a first source or drain region;
a second source or drain region; and
a channel region, wherein the channel region is adjacent the first source or drain region and the second source or drain region,
wherein an interface of the first source or drain region and the channel region has a dopant concentration gradient, wherein the dopant concentration gradient has a logarithmic slope of the dopant concentration of at least one order of magnitude per nanometer.

2. The device of claim 1, wherein the first source or drain region has a first dopant concentration level at a first position, wherein the channel region has a second dopant concentration level at a second position, wherein the first dopant concentration level is at least two orders of magnitude higher than the second dopant concentration level, wherein the second position is less than two nanometers away from the first position.

3. The device of claim 1, wherein the gate-all-around transistor is an NMOS transistor,
wherein an interface of the first source or drain region and the channel region has a phosphorous dopant concentration gradient, wherein the phosphorous dopant concentration gradient has a logarithmic slope of the dopant concentration of at least one order of magnitude per nanometer.

4. The device of claim 1, wherein a phosphorous dopant concentration in the first source or drain region is more than 5 times 10¹⁹ per cubic centimeter, wherein a phosphorous dopant concentration in the channel region is less than 5 times 10¹⁸ per cubic centimeter.

5. The device of claim 1, wherein the gate-all-around transistor further comprises a third source or drain region and a fourth source or drain region, wherein the third source or drain region is adjacent the first source or drain region, wherein the fourth source or drain region is adjacent the second source or drain region,
wherein the first source or drain region has a higher dopant concentration than the third source or drain region, wherein the second source or drain region has a higher dopant concentration than the fourth source or drain region,
wherein a first back side power contact is adjacent the first source or drain region, wherein a second back side power contact is adjacent the second source or drain region, wherein a first front side logic contact is adjacent the third source or drain region, wherein a second front side logic contact is adjacent the fourth source or drain region.

6. The device of claim 1, wherein, at a cross-sectional side view, the first source or drain region has a U shape, wherein a thickness of the first source or drain region is between 1 and 3 nanometers,
wherein, at a cross-sectional side view, the second source or drain region has a U shape, wherein a thickness of the second source or drain region is between 1 and 3 nanometers.

7. The device of claim 1, further comprising a processor, wherein the processor comprises the gate-all-around transistor.

8. The device of claim 7, further comprising one or more memory devices communicatively coupled to the processor.

9. A device comprising:
a transistor comprising:
a first region, wherein the first region has a first dopant concentration;
a second region, wherein the second region has a second dopant concentration; and
an interface region, the interface region between the first region and the second region and adjacent the first region and the second region,
wherein the interface region has a dopant concentration gradient from the first region to the second region, wherein the dopant concentration gradient has a logarithmic slope of the dopant concentration of at least one order of magnitude per nanometer, wherein at least part of the interface region has a dopant concentration less than 10¹⁹ per cubic centimeter and at least part of the interface region has a dopant concentration more than 10¹⁹ per cubic centimeter.

10. The device of claim 9, wherein the first region is a source/drain region, wherein the second region is a channel region, wherein the source/drain region has a first dopant concentration level at a first position, wherein the channel region has a second dopant concentration level at a second position, wherein the first dopant concentration level is at least two orders of magnitude higher than the second dopant concentration level, wherein the second position is less than two nanometers away from the first position.

11. The device of claim 9, wherein the transistor is an NMOS gate-all-around transistor,
wherein the interface region has a phosphorous dopant concentration gradient, wherein the phosphorous dopant concentration gradient has a logarithmic slope of the dopant concentration of at least one order of magnitude per nanometer.

12. The device of claim 9, wherein a phosphorous dopant concentration in the first region is more than 5 times 10¹⁹ per cubic centimeter, wherein a phosphorous dopant concentration in the second region is less than 5 times 10¹⁸ per cubic centimeter.

13. The device of claim 9, wherein the first region is a first source or drain region, wherein the second region is a second source or drain region, wherein the transistor further comprises a channel region, the second source or drain region adjacent the channel region.

14. The device of claim 9, wherein the second region comprises one or more nubs extending to a point at one or both ends of the second region.

15. The device of claim 9, wherein, at a cross-sectional side view, the first region has a U shape, wherein a thickness of the first region is between 1 and 3 nanometers.

16. The device of claim 9, further comprising a processor, wherein the processor comprises the transistor.

17. A method for creating a transistor, the method comprising:
performing one or more high temperature semiconductor processing steps at a temperature about 500° C.; and
after performing the one or more high temperature semiconductor processing steps, growing a silicon region at a temperature of less than 450° C., the silicon region comprising a dopant concentration of at least 10²⁰ per cubic centimeter, wherein growing the silicon region comprises alternately flowing deposition gases and flowing an etchant gas.

18. The method of claim 17, wherein the etchant gas comprises chlorine.

19. The method of claim 17, wherein performing the one or more high temperature semiconductor processing steps comprises depositing a gate dielectric, a gate, or both the gate dielectric and the gate.

20. The method of claim 17, further comprising:
depositing a sacrificial material before performing the one or more high temperature semiconductor processing steps; and
removing the sacrificial material after performing the one or more high temperature semiconductor processing steps and before growing the silicon region.
